(19) United States
(12) Patent Application Publication
(10) Pub. No.: US 2020/0185403 A1
(43) Pub. Date: Jun. 11, 2020

(54) SEMICONDUCTOR MEMORY DEVICE

(71) Applicant: Toshiba Memory Corporation, Minato-ku (JP)

(72) Inventors: Kohei NYUI, Yokkaichi (JP); Takayuki KASHIMA, Yokkaichi (JP)

(73) Assignee: Toshiba Memory Corporation, Minato-ku (JP)

(21) Appl. No.: 16/522,754

(22) Filed: Jul. 26, 2019

(30) Foreign Application Priority Data
Dec. 5, 2018 (JP) 2018-228428

(51) Int. Cl. H01L 27/11578; H01L 27/1157; H01L 29/78; H01L 29/792; H01L 29/66

(52) U.S. Cl. CPC H01L 27/11578; H01L 27/1157; H01L 29/66833; H01L 29/7926; H01L 29/7827

(57) ABSTRACT

A semiconductor memory device according to an embodiment includes first and second conductive layers and first and second pillar. The first pillar penetrates the first conductive layers, and includes one part of a first semiconductor layer. The second pillar penetrates the second conductive layer and is provided on the first pillar. The second pillar includes another part of the first semiconductor layer. An area of the second pillar is smaller than an area of the first pillar. The first semiconductor layer includes a first portion facing an uppermost one of the first conductive layers and a second portion facing the second conductive layer. The first semiconductor layer is continuous at least from the first portion to the second portion.

### CROSS-REFERENCE TO RELATED APPLICATIONS

This application is based upon and claims the benefit of priority from Japanese Patent Application No. 2018-228428, filed Dec. 5, 2018, the entire contents of which are incorporated herein by reference.

### FIELD

Embodiments described herein relate generally to a semiconductor memory device.

### BACKGROUND

A NAND-type flash memory capable of storing data in a nonvolatile manner is known.

### BRIEF DESCRIPTION OF THE DRAWINGS

FIG. 1 is a block diagram showing a configuration example of a semiconductor memory device according to a first embodiment.

FIG. 2 is a circuit diagram showing an example of a circuit configuration of a memory cell array included in the semiconductor memory device according to the first embodiment.

FIG. 3 is a plan view showing an example of a planar layout of the memory cell array included in the semiconductor memory device according to the first embodiment.

FIG. 4 is a cross-sectional view showing an example of a cross-sectional structure of the memory cell array along an IV-IV line in FIG. 3.

FIG. 5 is a cross-sectional view showing an example of a cross-sectional structure of a memory pillar along a V-V line in FIG. 4.

FIG. 6 is a cross-sectional view showing an example of a cross-sectional structure of the memory pillar along a VI-VI line in FIG. 4.

FIG. 7 is a flowchart showing an example of a manufacturing method of the semiconductor memory device according to the first embodiment.

FIGS. 8, 9, 10, 11, 12, 13, 14, 15, 16, 17, 18, 19, 20, 21, 22, 23, and 24 constitute a cross-sectional view of the memory cell array, showing an example of a step in the process of manufacturing the semiconductor memory device according to the first embodiment.

FIG. 25 is a cross-sectional view showing an example of a cross-sectional structure of a memory cell array included in a semiconductor memory device according to a second embodiment.

FIG. 26 is a cross-sectional view for comparing the structure of the memory pillar according to the first embodiment with the structure of a memory pillar according to the second embodiment.

FIG. 27 is a flowchart showing an example of a manufacturing method of the semiconductor memory device according to the second embodiment.

FIGS. 28 and 29 constitute a cross-sectional view of the memory cell array showing an example of a step in the process of manufacturing the semiconductor memory device according to the second embodiment.

FIG. 30 is a cross-sectional view showing an example of a cross-sectional structure of a memory cell array included in a semiconductor memory device according to a third embodiment.

FIG. 31 is a cross-sectional view showing an example of a cross-sectional structure of a memory cell array included in a semiconductor memory device according to a fourth embodiment.

FIG. 32 is a cross-sectional view showing an example of a cross-sectional structure of a memory pillar along a XXXII-XXXII line in FIG. 31.

FIG. 33 is a plan view showing an example of a planar layout of a memory cell array included in a semiconductor memory device according to a modification of the first embodiment.

FIG. 34 is a cross-sectional view showing an example of a cross-sectional structure of the memory cell array included in the semiconductor memory device according to the modification of the first embodiment.

### DETAILED DESCRIPTION

In general, according to one embodiment, a semiconductor memory device includes a plurality of first conductive layers, a second conductive layer, a first pillar, and a second pillar. The first conductive layers are stacked in a first direction above a substrate. The first conductive layers are separated from each other. The second conductive layer is provided above the first conductive layers. The first pillar is provided so as to penetrate the first conductive layers. The first pillar includes one part of a first semiconductor layer extending in the first direction, and a portion where the first pillar crosses each of the first conductive layers functions as a memory cell transistor. The second pillar penetrate the second conductive layer and is provided on the first pillar. The second pillar includes another part of the first semiconductor layer, and a portion where the second pillar crosses the second conductive layer functions as a select transistor. An area of the second pillar in a cross-section parallel to the substrate and including the second conductive layer is smaller than an area of the first pillar in a cross-section parallel to the substrate and including one of the first conductive layers. The first semiconductor layer includes a first portion facing an uppermost one of the first conductive layers and a second portion facing the second conductive layer. The first semiconductor layer is continuous at least from the first portion to the second portion.

Hereinafter, the embodiments will be described with reference to the accompanying drawings. Each embodiment is an example of an apparatus or a method for embodying a technical idea of the invention. It should be noted that the drawings are schematic or conceptual, and that the dimensions and scales of the drawings are not necessarily the same as those of the actual products. The technical idea of the present invention is not specified by the shape, structure, arrangement, etc. of structural elements.

In the explanation below, structural elements having the same functions and configurations will be denoted by the same reference symbols. The numbers after the letters constituting the reference symbols are used to distinguish elements denoted by reference symbols including the same letters and with similar configurations. If there is an absence of need to mutually distinguish the elements denoted by the reference symbols including the same letters, the same elements are denoted by the reference symbols including the letters only.

### [1] First Embodiment

Hereinafter, a semiconductor memory device 1 according to a first embodiment will be described.

[1-1] Configuration of Semiconductor Memory Device 1

[1-1-1] Overall Configuration of Semiconductor Memory Device 1

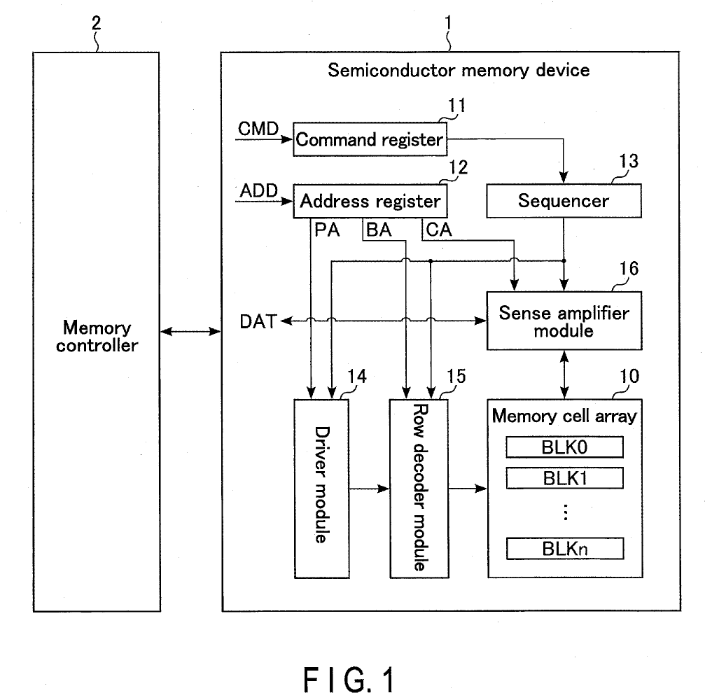

FIG. 1 shows a configuration example of a semiconductor memory device 1 according to a first embodiment. The semiconductor memory device 1 is a NAND-type flash memory capable of storing data in a non-volatile manner. The semiconductor memory device 1 is controlled by an external memory controller 2. Communication between the semiconductor memory device 1 and the memory controller 2 supports a NAND interface standard, for example.

As shown in FIG. 1, the semiconductor memory device 1 includes a memory cell array 10, a command register 11, an address register 12, a sequencer 13, a driver module 14, a row decoder module 15, and a sense amplifier module 16, for example.

The memory cell array 10 includes a plurality of blocks BLK0 to BLKn (n is an integer equal to or greater than 1). A block BLK is a group of a plurality of memory cells capable of storing data in a non-volatile manner, and is used as, for example, a data erasure unit. In the memory cell array 10, a plurality of bit lines and a plurality of word lines are provided. Each memory cell is associated with a single bit line and a single word line, for example. A detailed configuration of the memory cell array 10 will be described later.

The command register 11 retains a command CMD that is received by the semiconductor memory device 1 from the memory controller 2. The command CMD includes commands which cause the sequencer 13 to execute a read operation, a write operation, and an erase operation, for example.

The address register 12 retains address information ADD received by the semiconductor memory device 1 from the memory controller 2. The address information ADD includes a block address BA, a page address PA, and a column address CA, for example. The block address BA, the page address PA, and the column address CA are, for example, respectively used for selecting a block BLK, a word line, and a bit line.

The sequencer 13 controls the operation of the entire semiconductor memory device 1. For example, the sequencer 13 performs a read operation, a write operation, and an erase operation by controlling the driver module 14, the row decoder module 15, and the sense amplifier module 16, etc. based on a command CMD retained in the command register 11.

The driver module 14 generates a voltage to be used in a read operation, a write operation, and an erase operation, etc. The driver module 14 applies the generated voltage to a signal line corresponding to the selected word line based on a page address PA retained in the address register 12, for example.

The row decoder module 15 selects one block BLK in a corresponding memory cell array 10, based on the block address BA retained in the address register 12. The row decoder module 15 transfers the voltage applied to the signal line, corresponding to the selected word line, to the selected word line in the selected block BLK, for example.

The sense amplifier module 16, in a write operation, applies a desired voltage to each bit line in accordance with write data DAT received from the memory controller 2. The sense amplifier module 16, in a read operation, determines data stored in a memory cell based on the voltage of the bit line, and transfers the determination result as read data DAT to the memory controller 2.

The semiconductor memory device 1 and the memory controller 2 as described above may be combined to constitute one semiconductor device. Such a semiconductor device may be a memory card, such as an SD™ card, and an SSD (solid state drive).

[1-1-2] Circuit Configuration of Memory Cell Array 10

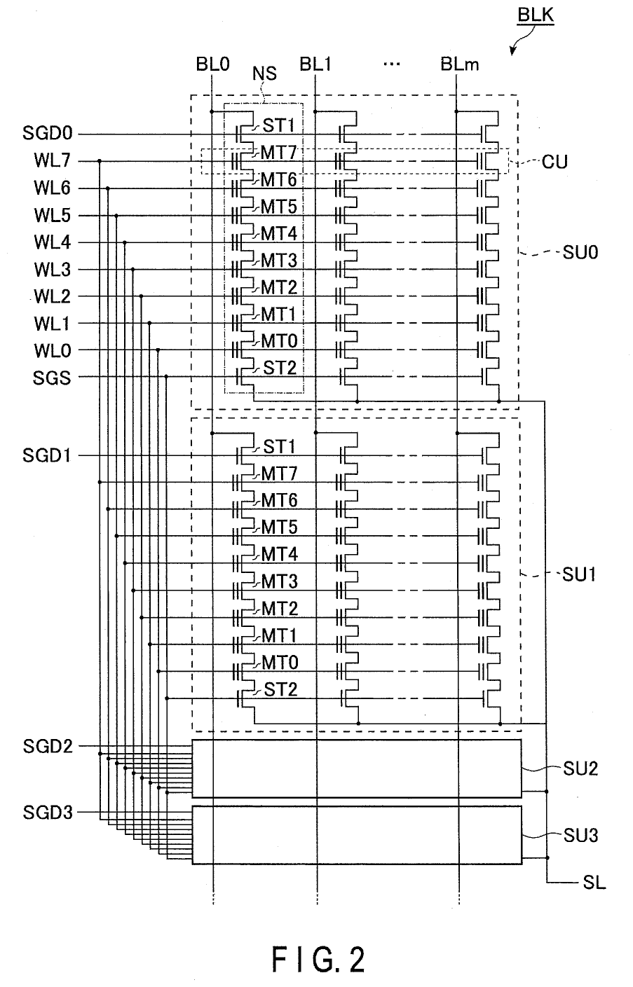

FIG. 2 shows an example of a circuit configuration of the memory cell array 10 included in the semiconductor memory device 1 according to the first embodiment, and focuses on one block BLK of the plurality of blocks BLK included in the memory cell array 10. As shown in FIG. 2, the block BLK includes four string units SU0 to SU3, for example.

Each string unit SU includes a plurality of NAND strings NS respectively associated with bit lines BL0 to BLm (where m is an integer equal to or greater than 1). Each NAND string NS includes memory cell transistors MT0 to MT7 and select transistors ST1 and ST2, for example. Each memory cell transistor MT includes a control gate and a charge storage layer, and retains data in a non-volatile manner. Each of the select transistors ST1 and ST2 is used to select the string unit SU in various operations.

In each NAND string NS, the memory cell transistors MT0 to MT7 are coupled in series. A drain of a select transistor ST1 is coupled to an associated bit line BL, and a source of the select transistor ST1 is coupled to one end of the memory cell transistors MT0 to MT7 (which are coupled in series). A drain of a select transistor ST2 is coupled to the other end of the memory cell transistors MT0 to MT7 (which are coupled in series). Sources of the select transistors ST2 are coupled to the source line SL.

The control gates of the memory cell transistors MT0 to MT7 in the same block BLK are respectively coupled in common to word lines WL0 to WL7. The gates of the select transistor ST1 in the string units SU0 to SU3 are respectively coupled in common to the select gate lines SGD0 to SGD3. The gates of the select transistors ST2 are coupled in common to a select gate line SGS.

In the circuit configuration of the memory cell array 10 described above, the bit line BL is coupled in common to a plurality of corresponding NAND strings NS in each string unit SU, to which the same column address is allocated. The source line SL is coupled in common to a plurality of blocks BLK, for example.

A group of the plurality of memory cell transistors MT coupled to a common word line WL in one string unit SU is called, for example, a “cell unit CU”. For example, a storage capacity of the cell unit CU, including memory cell transistors MT each storing 1-bit data, is defined as “one-page data.” The storage capacity of the cell unit CU may be two-page data or more in accordance with the number of bits of data stored in the memory cell transistors MT.

The circuit configuration of the memory cell array 10 included in the semiconductor memory device 1 according to the first embodiment is not limited to the configuration described above. For example, each of the numbers of the memory cell transistors MT, and the select transistors ST1 and ST2, included in each NAND string NS may be determined as a given number. The number of string units SU included in each block BLK may be determined as a given number.

[1-1-3] Structure of Memory Cell Array 10

An example of the structure of the memory cell array 10 according to the first embodiment will be explained below.

In the drawings referred to below, the X-axis direction corresponds to the extending direction of bit lines BL. The Y-axis direction corresponds to the extending direction of the word lines WL. The Z-axis direction corresponds to a vertical direction relative to the surface of the semiconductor substrate 20 on which the semiconductor memory device 1 is formed. In the plan view, hatching is suitably added for better viewability. The hatching added to the plan view is not necessarily related to materials or characteristics of the hatched structural elements. In the cross-sectional view, structural elements such as an insulation layer (an interlayer insulation film), a wire, and a contact are suitably omitted for better viewability.

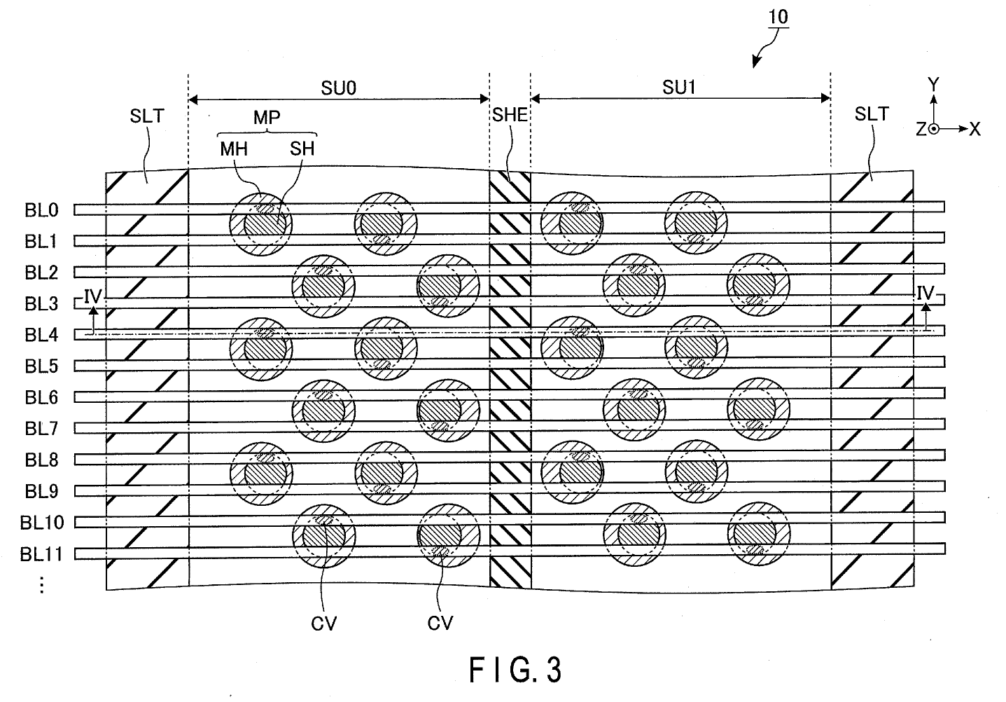

FIG. 3 is an example of a planar layout of the memory cell array 10 included in the semiconductor memory device 1 according to the first embodiment, and focuses on structures respectively corresponding to the string units SU0 and SU1. As shown in FIG. 3, the memory cell array 10 includes slits SLT, SHE, memory pillars MP, contacts CV, and bit lines BL, for example.

The plurality of slits SLT respectively extend in the Y-axis direction, and are arranged in the X-axis direction. A slit SHE extends in the Y-axis direction and is arranged between neighboring slits SLT. The slit SLT is wider than the slit SHE. The slit SLT and the slit SHE respectively include an insulator. The slit SLT divides each of the interconnect layers corresponding to the word lines WL, an interconnect layer corresponding to the select gate line SGD, and an interconnect layer corresponding to the select gate line SGS. The slit SHE divides the interconnect layer corresponding to the select gate line SGD.

An area sectioned by the slits SLT and SHE corresponds to one string unit SU. Specifically, string units SU0 and SU1 are provided between slits SLT that are neighboring in the X-axis direction, for example. In this case, the slit SHE is provided between the string units SU0 and SU1. In the memory cell array 10, for example, the same layout is repeatedly provided in the X-axis direction.

The plurality of memory pillars MP are arranged in a staggered manner in an area corresponding to the string unit SU, for example. Each of the memory pillars MP has a portion formed in the memory hole MH and a portion formed in the SGD hole SH. The SGD hole SH is provided in a higher layer than the memory hole MH, and has a diameter smaller than that of the memory hole MH. A set of corresponding memory hole MH and corresponding SGD hole SH have portions which overlap each other, in the plan view. Also, in the plan view, a center of a corresponding memory hole MH may, or may not overlap with a center of the corresponding SGD hole SH or may not overlap.

If the center of the corresponding memory hole MH does not overlap with the center of the corresponding SGD hole SH, the positional relationship between the overlapping memory hole MH and SGD hole SH varies according to the positional relationship between the memory pillar MP and the slits SLT and SHE. For example, the SGD hole SH of a memory pillar MP in the vicinity of the slit SLT is provided away from the slit SLT. Similarly, the SGD hole SH in a memory pillar MP in the vicinity of the slit SHE is provided away from the slit SHE.

In other words, the SGD hole SH is provided so as to tilt toward an intermediate position between slits SLT and SHE, which are neighboring in the X-axis direction. As the length between the center position of the memory hole MH and the center position of the SGD hole SH increases, so the space between a corresponding memory pillar MP and the corresponding slits SLT and SHE becomes narrower. Thus, the memory cell array 10 is designed in a layout avoiding contact between the slit SHE and the SGD hole SH.

The plurality of bit lines BL respectively extend in the X-axis direction, and are arranged in the Y-axis direction. Each bit line BL is arranged so as to overlap with at least one SGD hole SH in each string unit SU. For example, two bit lines BL overlap with each SGD hole SH. A contact CV is provided between one bit line BL among a plurality of bit lines BL overlapping with an SGD hole SH and the SGD hole SH. The structure residing in the SGD hole SH is electrically coupled to a corresponding bit line BL via the contact CV.

The planar layout of the memory cell array 10 described above is merely an example and is not limited thereto. For example, the number of slits SHE provided between neighboring slits SLT may be determined as a given number. The number of string units SU between neighboring slits SLT varies based on the number of slits SHE. The number and arrangement of the memory pillars MP may be determined discretionarily. The number of bit lines BL overlapping with each memory pillar MP may be determined as a given number.

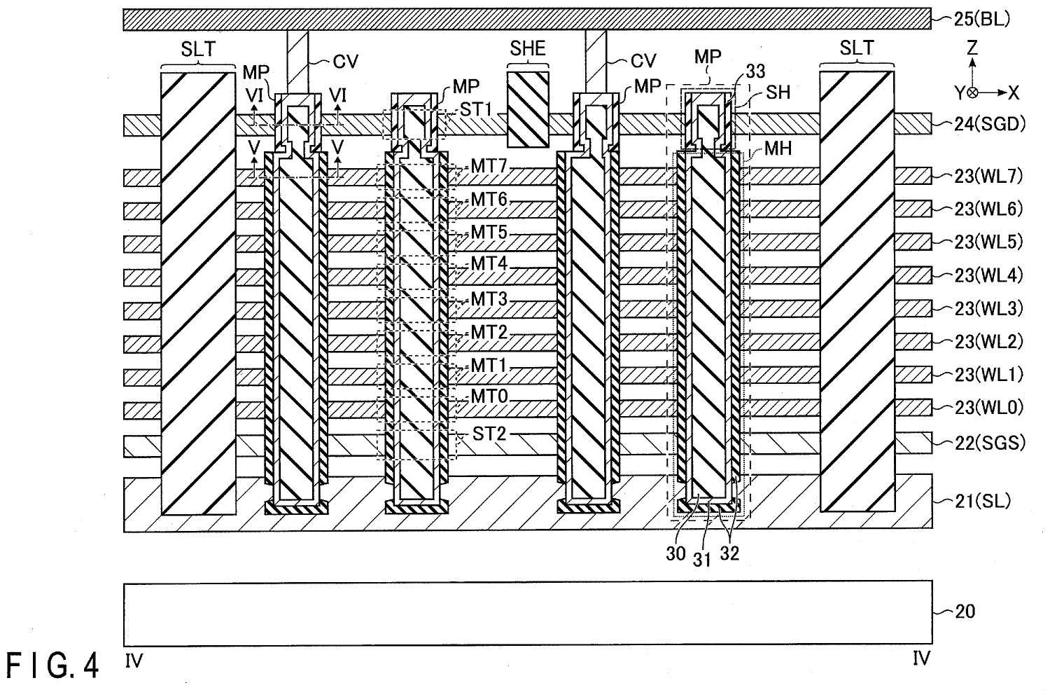

FIG. 4 is a cross-sectional view along an IV-IV line in FIG. 3 and shows an example of a cross-sectional structure of the memory cell array 10 included in the semiconductor memory device 1 according to the first embodiment. As shown in FIG. 4, the memory cell array 10 further includes conductive layers 21 to 25, for example. The conductive layers 21 to 25 are provided above the semiconductor substrate 20.

Specifically, a conductive layer 21 is provided above the semiconductor substrate 20 with an insulation layer interposed therebetween. For example, a circuit (not shown), such as the sense amplifier module 16, is provided on an insulation layer between the semiconductor substrate 20 and the conductive layer 21. The conductive layer 21 is formed in a plate-like shape extending along the X-Y plane, and is used as a source line SL, for example. The conductive layer 21 includes silicon (Si), for example.

A conductive layer 22 is provided above the conductive layer 21 with an insulation layer interposed therebetween. The conductive layer 22 is formed in a plate-like shape extending along the X-Y plane, and is used as a select gate line SGS. The conductive layer 22 includes silicon (Si), for example.

The insulation layers and the conductive layers 23 are alternately stacked above the conductive layer 22. A conductive layer 23 is formed in a plate-like shape extending along the X-Y plane, for example. The stacked conductive layers 23 are respectively used as word lines WL0 to WL7, from the side of the semiconductor substrate 20. The conductive layers 23 include tungsten (W), for example.

A conductive layer 24 is provided above an uppermost layer of the conductive layers 23, with an insulation layer being interposed therebetween. The conductive layer 24 is formed in a plate-like shape extending along the X-Y plane, and is used as a select gate line SGD, for example. A space between the uppermost layer of the conductive layers 23 and the conductive layer 24 in a Z-axis direction is wider than a space between two adjacent layers of the conductive layers 23 in the Z-axis direction. In other words, a thickness of the insulation layer between the uppermost layer of the conductive layers 23 and the conductive layer 24 is thicker than a thickness of the insulation layer between two adjacent layers of the conductive layers 23. The conductive layers 24 include tungsten (W), for example.

A conductive layer 25 is provided above the conductive layer 24 with an insulation layer interposed therebetween. For example, the conductive layer 25 is formed in a linear shape extending along the X-axis direction, and is used as a bit line BL. Accordingly, a plurality of conductive layers 25 are arranged along the Y-axis direction in an area not shown. The conductive layer 25 includes copper (Cu), for example.

The memory pillar MP is provided so as to extend along the Z-axis direction, and penetrates the conductive layers 22 to 24. Specifically, a portion of the memory pillar MP corresponding to the memory hole MH penetrates the conductive layers 22 and 23, and a bottom thereof is in contact with the conductive layer 21. A portion of the memory pillar MP corresponding to the SGD hole SH is provided on the portion corresponding to the memory hole MH, and penetrates the conductive layer 24. A layer including a border between the memory hole MH and the SGD hole SH is included in the layer between the uppermost layer of the conductive layers 23 and the conductive layer 24.

The memory pillar MP includes a core member 30, a semiconductor layer 31, and multi-layered films 32 and 33, for example. The core member 30 and the semiconductor layer 31 are respectively included in the portion corresponding to the memory hole MH and the portion corresponding to the SGD hole SH. The multi-layered film 32 is included in the portion corresponding to the memory hole MH. The multi-layered film 33 is included in the portion corresponding to the SGD hole SH.

The core member 30 extends along the Z-axis direction. The top end of the core member 30 is included in, for example, a layer higher than that where the conductive layer 24 is provided. The bottom end of the core member 30 is included in a layer where the conductive layer 21 is provided, for example. For the outer diameter of the core member 30 in a cross-section parallel to the surface of the semiconductor substrate 20, a portion of the outer diameter facing the conductive layer 24 is smaller than a portion of the outer diameter facing the conductive layers 23. The outer diameter of the core member 30, in the vicinity of a border between the memory hole MH and the SGD hole SH, is smaller than the portion of the outer diameter of the core member 30 facing the conductive layer 24. The core member 30 includes an insulator such as oxide silicon (SiO₂).

The semiconductor layer 31 covers the core member 30. That is, the semiconductor layer 31 has a portion formed in a cylindrical shape in the memory hole MH and a portion formed in a cylindrical shape in the SGD hole SH. A part of the side surface of the semiconductor layer 31 provided in the memory hole MH is in contact with the conductive layer 21. For the outer diameter of the semiconductor layer 31 in a cross-section parallel to the surface of the semiconductor substrate 20, a portion of the outer diameter facing the conductive layer 24 is smaller than a portion of the outer diameter facing the conductive layers 23.

The semiconductor layer 31 is provided continuously between the portion corresponding to the memory hole MH and the portion corresponding to the SH. In other words, the semiconductor layer 31 is provided continuously between a portion of the semiconductor layer 31 facing at least the uppermost layer of the conductive layers 23 and a portion of the semiconductor layer 31 facing the conductive layer 24. The thickness of the portion of the semiconductor layer 31 corresponding to the conductive layer 24 is approximately equal to the thickness of the portion of the semiconductor layer 31 facing the conductive layer 23.

The multi-layered film 32 covers the side and bottom surfaces of the semiconductor layer 31 in the memory hole MH, except for the portion where the conductive layer 21 is in contact with the semiconductor layer 31. That is, the multi-layered film 32 includes the portion formed in a cylindrical shape in the memory hole MH.

The multi-layered film 33 covers a side surface of the semiconductor layer 31 in the SGD hole SH. That is, the multi-layered film 33 includes the portion formed in a cylindrical shape in the SGD hole SH. The multi-layered film 33 may have a portion provided along the lower surface of the semiconductor layer 31 in the vicinity of a border portion between the memory hole MH and the SGD hole SH.

The outer diameter of the multi-layered film 33 in the layer where the conductive layer 24 is provided is smaller than the outer diameter of the multi-layered film 32 in the layer where the conductive layer 23 is provided. The thickness of the multi-layered film 33 may be designed to be thinner than the thickness of the multi-layered film 32. The top surface of the multi-layered film 32 is separated from the bottom surface of the multi-layered film 33 at least in part.

A pillar-shape contact CV is provided on the top surface of the semiconductor layer 31 in the memory pillar MP. The area illustrated includes contacts CV corresponding to two memory pillars MP, among four memory pillars MP. In the area not illustrated in FIG. 4, a contact CV is coupled to each of the memory pillars MP not coupled to a contact CV in the illustrated area. The top surface of a contact CV is in contact with one conductive layer 25, in other words, one bit line BL.

The slit SLT is formed into a plate-like shape extending along a YZ-plane, and divides the conductive layers 22 to 24, for example. The top end of the slit SLT is included in the layer which is higher than the top end of the memory pillar MP and lower than the conductive layer 25. The bottom end of each of the slits SLT is included in the layer where the conductive layer 21 is provided, for example. The slit SLT includes an insulator such as silicon oxide (SiO₂), for example.

The slit SHE is formed into a plate-like shape extending along the YZ-plane, and divides the conductive layer 24, for example. The top end of the slit SHE is included in the layer which is higher than the top surface of the memory pillar MP and lower than the conductive layer 25. Each bottom end of the slits SHE is included in a layer between a layer where the uppermost layer of the conductive layers 23 is provided and a layer where the conductive layer 24 is provided. The slits SHE include an insulator such as a silicon oxide (SiO₂), for example.

FIG. 5 is a cross-sectional view along the V-V line in FIG. 4 and shows an example of a cross-sectional structure of a memory pillar in the semiconductor memory device 1 according to the first embodiment. More specifically, FIG. 5 shows a cross-sectional structure in a portion corresponding to a memory hole MH of a memory pillar MP in a layer parallel to the surface of the semiconductor substrate 20 and which includes the conductive layer 23.

As shown in FIG. 5, in the layer including the conductive layer 23, the core member 30 is provided in a center portion of the memory pillar MP, for example. The semiconductor layer 31 surrounds the side surface of the core member 30. The multi-layered film 32 surrounds the side surface of the semiconductor layer 31. Specifically, the multi-layered film 32 includes a tunnel insulation film 34, an insulation film 35, and a block insulation film 36, for example.

The tunnel insulation film 34 surrounds the side surface of the semiconductor layer 31. The insulation film 35 surrounds the side surface of the tunnel insulation film 34. The block insulation film 36 surrounds the side surface of the insulation film 35. The conductive layer 23 surrounds the side surface of the block insulation film 36. The tunnel insulation film 34 and the block insulation film 36 respectively include silicon oxide (SiO₂), for example. The insulation film 35 includes silicon nitride (SiN), for example.

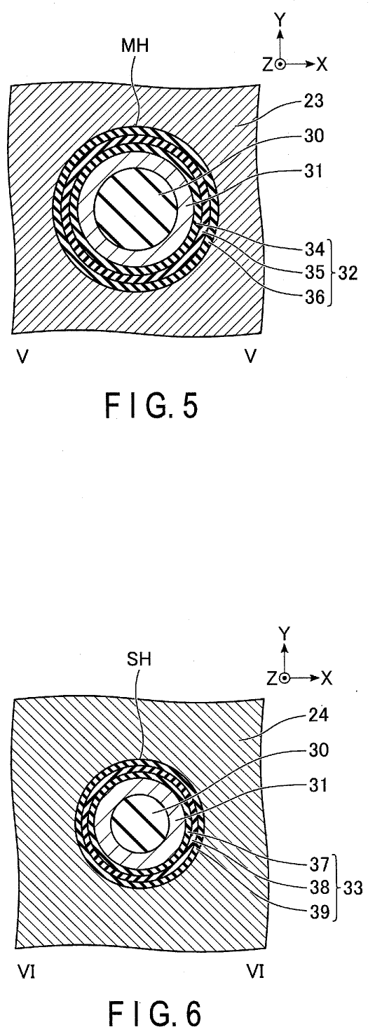

FIG. 6 is a cross-sectional view along a VI-VI line in FIG. 4, and shows an example of a cross-sectional structure of the memory pillar MP in the semiconductor memory device according to the first embodiment. More specifically, FIG. 6 shows a cross-sectional structure in a portion corresponding to an SGD hole SH of a memory pillar MP in the layer parallel to the surface of the semiconductor substrate 20 and which includes the conductive layer 24.

As shown in FIG. 6, in the layer including the conductive layer 24, the core member 30 is provided in a center portion of the SGD hole SH. The semiconductor layer 31 surrounds the side surface of the core member 30. The multi-layered film 33 surrounds the side surface of the semiconductor layer 31. Specifically, the multi-layered film 33 includes a tunnel insulation film 37, an insulation film 38, and a block insulation film 39, for example.

The tunnel insulation film 37 surrounds the side surface of the semiconductor layer 31. The insulation film 38 surrounds the side surface of the tunnel insulation film 37. The block insulation film 39 surrounds the side surface of the insulation film 38. The conductive layer 24 surrounds the side surface of the block insulation film 39. The tunnel insulation film 37 and the block insulation film 39 respectively include silicon oxide (SiO₂), for example. The insulation film 38 includes silicon nitride (SiN), for example.

In the structure of the memory pillar MP described above, the portion where the memory pillar MP crosses the conductor layer 22 functions as a select transistor ST2. The portion where the memory pillar MP crosses the conductive layer 23 functions as a memory cell transistor MT. The portion where the memory pillar MP crosses the conductive layer 24 functions as a select transistor ST1.

In other words, the semiconductor layer 31 is used as a channel for each of the memory cell transistors MT and the select transistors ST1 and ST2. The insulation film 35 is used as a charge storage layer of the memory cell transistor MT. With this configuration, each of the memory pillars MP functions as one NAND string NS, for example.

It should be noted that the structure of the memory cell array 10 described above is merely an example, and the memory cell array 10 may have other configurations. For example, the number of the conductive layers 23 is determined based on the number of the word lines WL. A plurality of conductive layers 22 provided in a plurality of layers may be allocated as select gate lines SGS. If the select gate lines SGS are provided in a plurality of layers, a conductor different from the conductive layer 22 may be used. A plurality of conductive layers 24 provided in a plurality of layers may be allocated as select gate lines SGD.

The memory pillar MP and the conductive layer 25 may be electrically coupled via two or more contacts, or alternatively via other wires. The slit SLT may include multiple types of insulators. For example, before the slit SLT is filled with silicon oxide, silicon nitride (SiN) may be formed as a side wall of the slit SLT. A space may be formed inside the core member 30. The space may be formed in a portion of the memory pillar MP corresponding to the memory hole MH, for example.

[1-2] Manufacturing Method of Semiconductor Memory Device 1

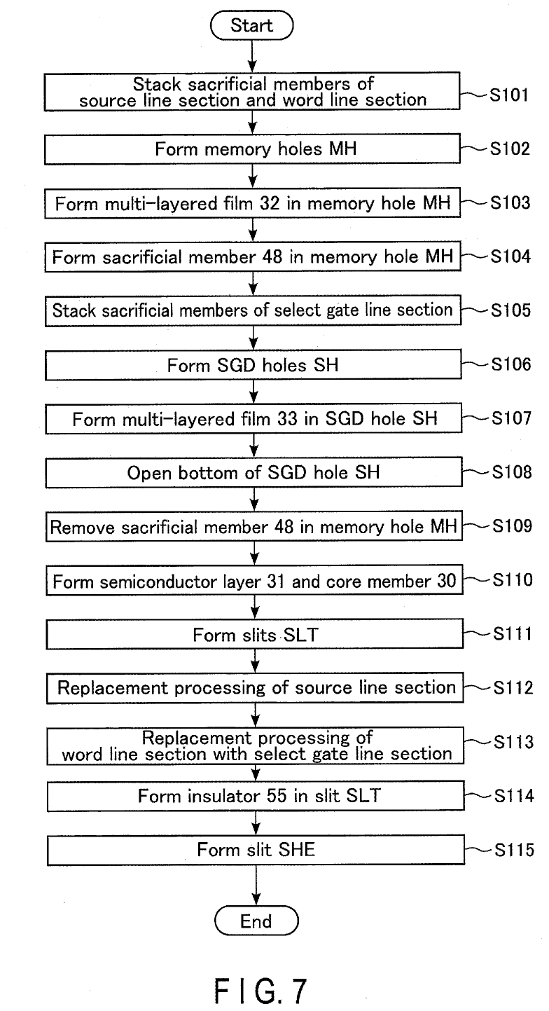

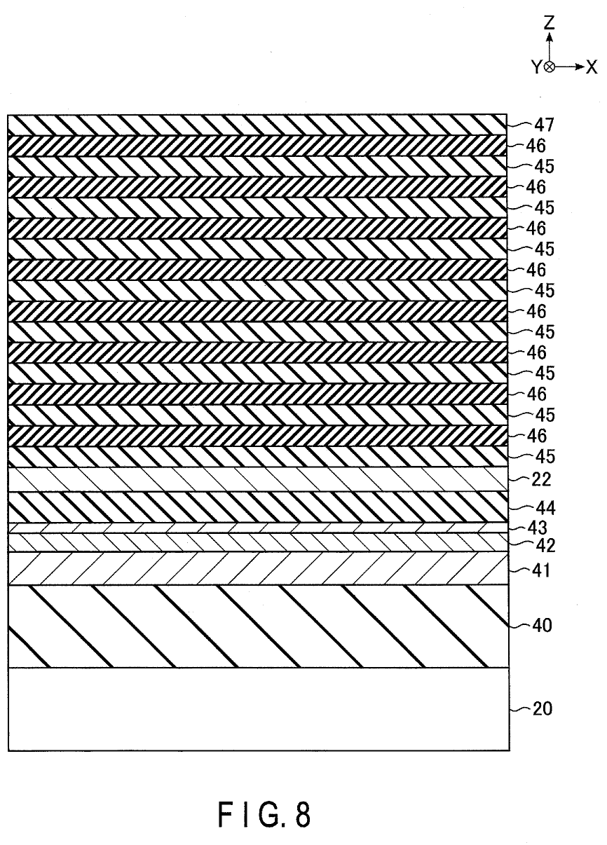

With reference to FIG. 7, an example of the series of manufacturing steps from formation of a stacked structure corresponding to the source line SL to formation of the slit SHE in the semiconductor memory device 1, according to the first embodiment, will be described. FIG. 7 is a flowchart showing an example of a manufacturing method of the semiconductor memory device 1 according to the first embodiment. Each of FIGS. 8 to 24 shows an example of a cross-sectional structure including a structure corresponding to the memory cell array 10 in a manufacturing step for the semiconductor memory device 1, according to the first embodiment.

First, the processing of step S101 is performed to stack a plurality of sacrificial members of a source line section and a word lines section. Specifically, as shown in FIG. 8, an insulation layer 40, a conductive layer 41, a sacrificial member 42, a conductive layer 43, an insulation layer 44, and a conductive layer 22 are formed sequentially on the semiconductor substrate 20. Insulation layers 45 and sacrificial members 46 are alternately stacked on the conductive layer 22. An insulation layer 47 is formed on an uppermost layer of the sacrificial members 46. A circuit corresponding to a sense amplifier module 16, etc. (not shown) is formed inside the insulation layer 40.

A set of the conductive layers 41, 43 and the sacrificial member 42 corresponds to the source line section. The conductive layers 41 and 43 respectively include silicon (Si), for example. The sacrificial member 42 is of a material capable of having a high etching selection ratio with respect to each of the conductive layers 41 and 43. The insulation layers 44, 45, and 47 respectively include silicon oxide (SiO₂), for example. Each of the sacrificial members 46 corresponds to the word line. For example, the number of layers in which the sacrificial members 46 are formed corresponds to the number of word lines WL that are stacked. The sacrificial member 46 includes silicon nitride (SiN), for example.

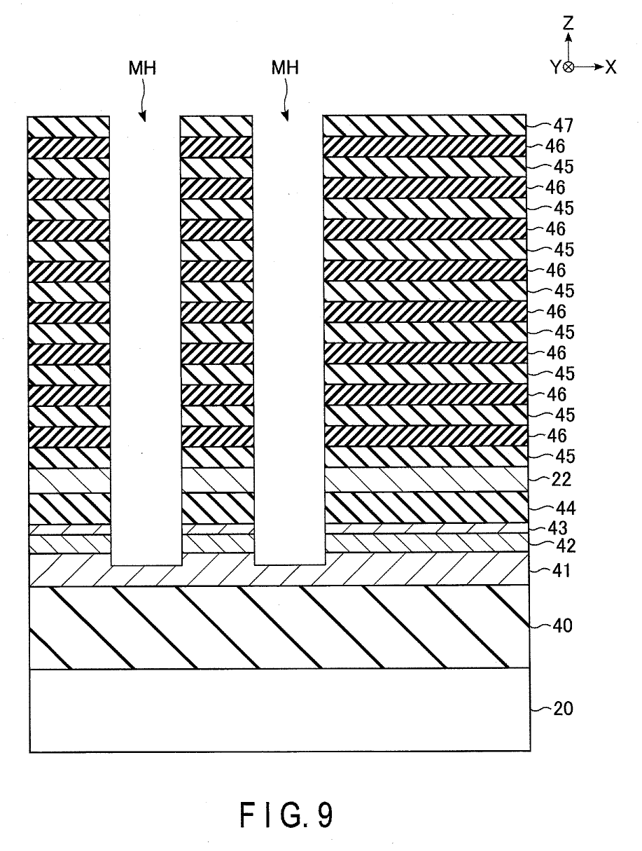

Next, the processing of step S102 is performed to form a memory hole MH. Specifically, as shown in FIG. 9, first, a mask in which areas corresponding to the memory holes MH are opened is formed by photolithography, etc. Then, the memory holes MH are formed by anisotropic etching using the formed mask.

Each of the memory holes MH formed in this step penetrates each of the insulation layers 44, 45, 47, the sacrificial members 42, 46, and the conductive layers 22, 43. The bottom of each of the memory hole MH ends in the conductive layer 41, for example. The anisotropic etching in this step is RIE (Reactive Ion Etching), for example.

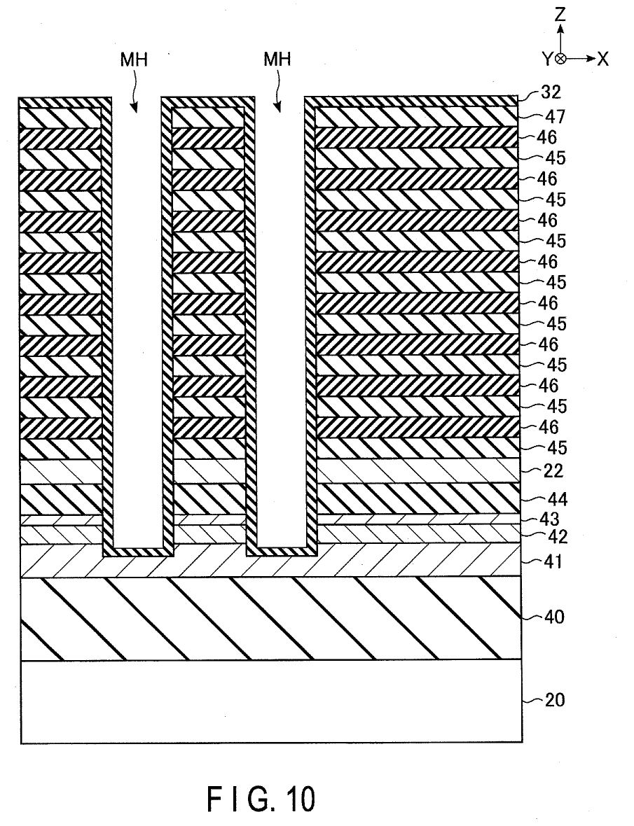

Next, the processing of step S103 is performed to form a multi-layered film 32 in the memory holes MH. Specifically, as shown in FIG. 10, the multi-layered film 32 is formed on the side and bottom surfaces of each of the memory holes MH, and on the top surface of the insulation layer 47. In other words, the block insulation film 36, the insulation film 35, and the tunnel insulation film 34 are formed sequentially.

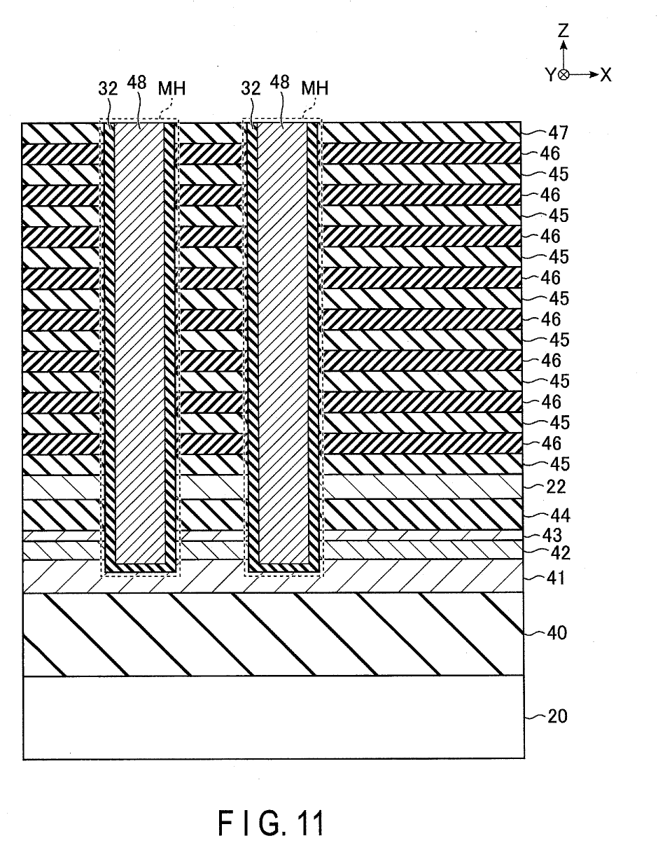

Next, the processing of step S104 is performed to form a sacrificial member 48 in each of the memory holes MH. Specifically, as shown in FIG. 11, first, the sacrificial member 48 is formed so as to fill the memory holes MH. The sacrificial member 48 and multi-layered film 32 formed in parts other than the memory holes MH are removed by, for example, CMP (Chemical Mechanical Polishing). The sacrificial member 48 is amorphous silicon, for example.

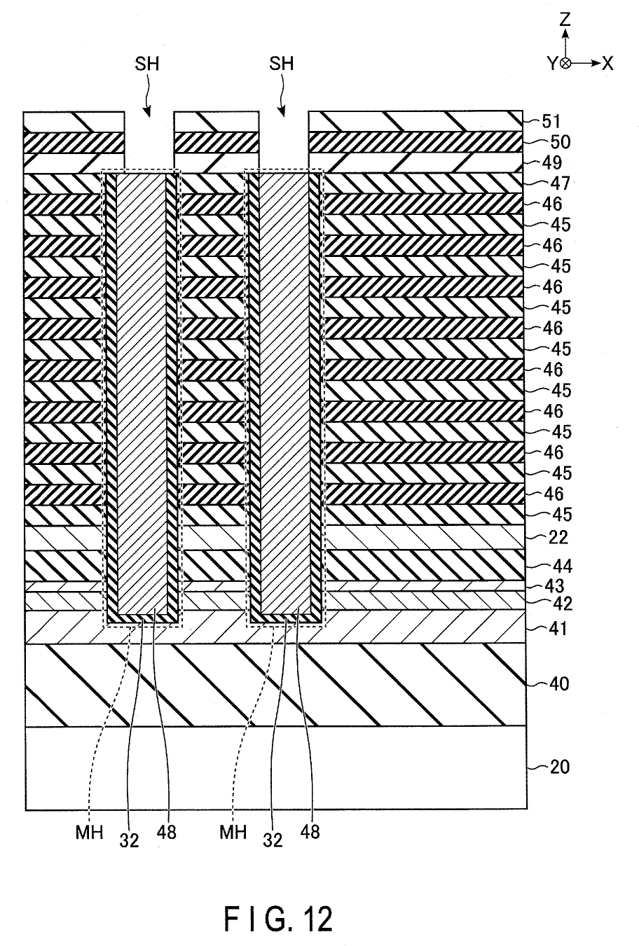

Next, the sacrificial member in a select gate line section is stacked through the processing of step S105, followed by forming SGD holes SH through the processing of step S106. Specifically, as shown in FIG. 12, first, an insulation layer 49, a sacrificial member 50, and insulation layer 51 are stacked sequentially. Then, a mask in which areas corresponding to the SGD holes SH are opened is formed by photolithography, etc. The SGD holes SH are then formed by anisotropic etching using the formed mask.

The SGD hole SH formed in this step penetrates each of the insulation layers 49, 51, and the sacrificial member 50. The bottom of each of the SGD holes SH stops inside a layer in which the insulation layer 47 is formed, for example. The SGD hole SH is processed such that at least the bottom thereof is positioned in a layer higher than the uppermost layer of the sacrificial members 46, and the sacrificial member 48 inside the corresponding memory hole MH is exposed. The anisotropic etching in this step is RIE (Reactive Ion Etching), for example.

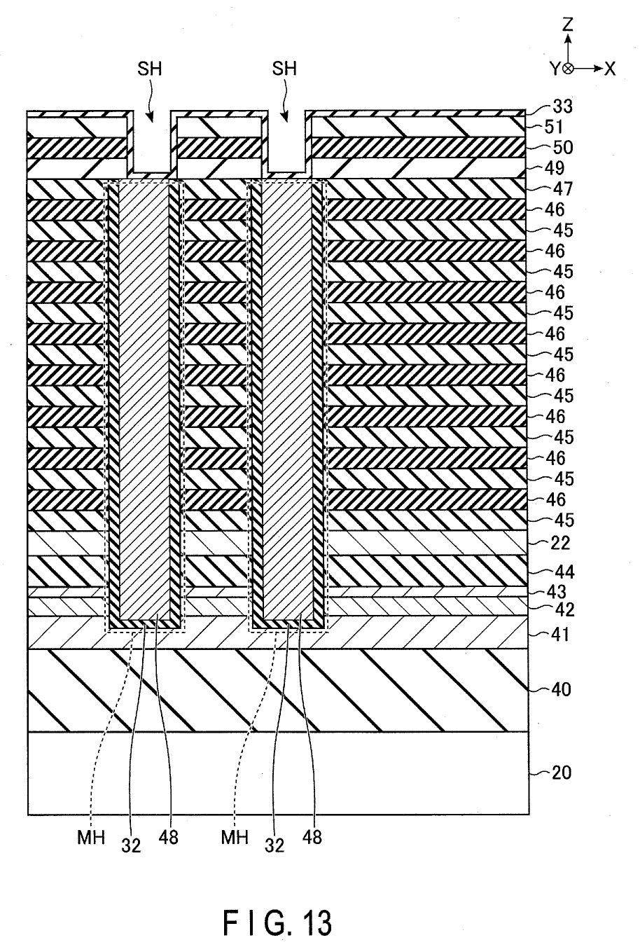

Next, the processing of step S107 is performed to form a multi-layered film 33 in each of the SGD holes SH. Specifically, as shown in FIG. 13, the multi-layered film 33 is formed on the side and bottom surfaces of the SGD hole SH and on the top surface of the insulation layer 51. In other words, a block insulation film 39, an insulation film 38, and a tunnel insulation film 37 are formed sequentially.

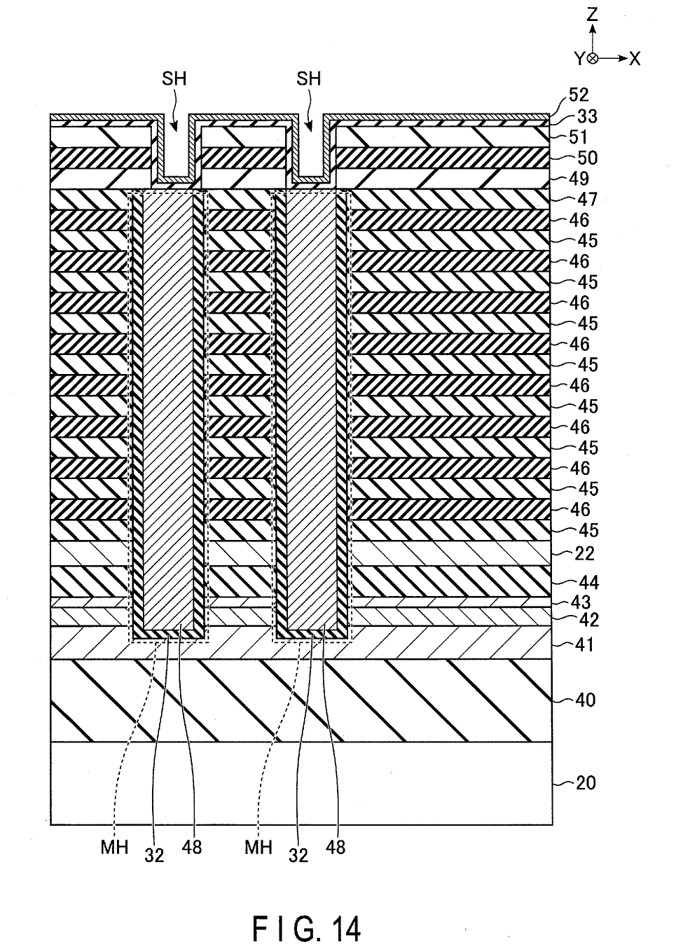

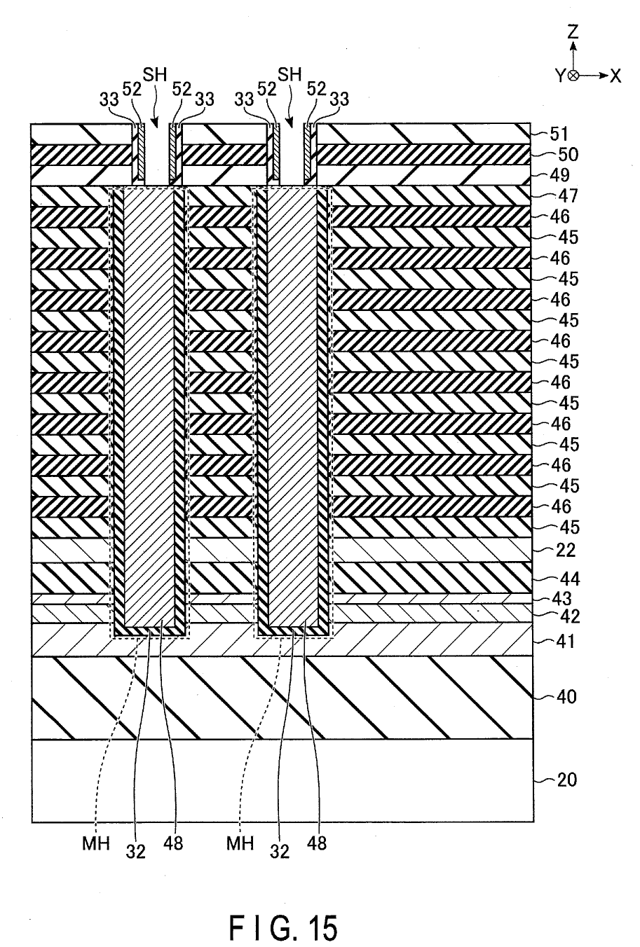

Next, the processing of step S108 is performed to open the bottom of each of the SGD holes SH. Specifically, as shown in FIG. 14, first, a passivation film 52 is formed on a surface of the multi-layered film 33. The passivation film 52 is formed of amorphous silicon, for example. Subsequently, as shown in FIG. 15, the multi-layered film 33 and passivation film 52, formed in portions other than the SGD holes SH, and the multi-layered film 33 and the passivation film 52, formed in the bottom of each of the SGD holes SH, are removed. In this step, anisotropic etching is performed such that the sacrificial member 48 inside the memory holes MH is exposed at least at the bottom of each of the SGD holes SH. The anisotropic etching in this step is RIE, for example.

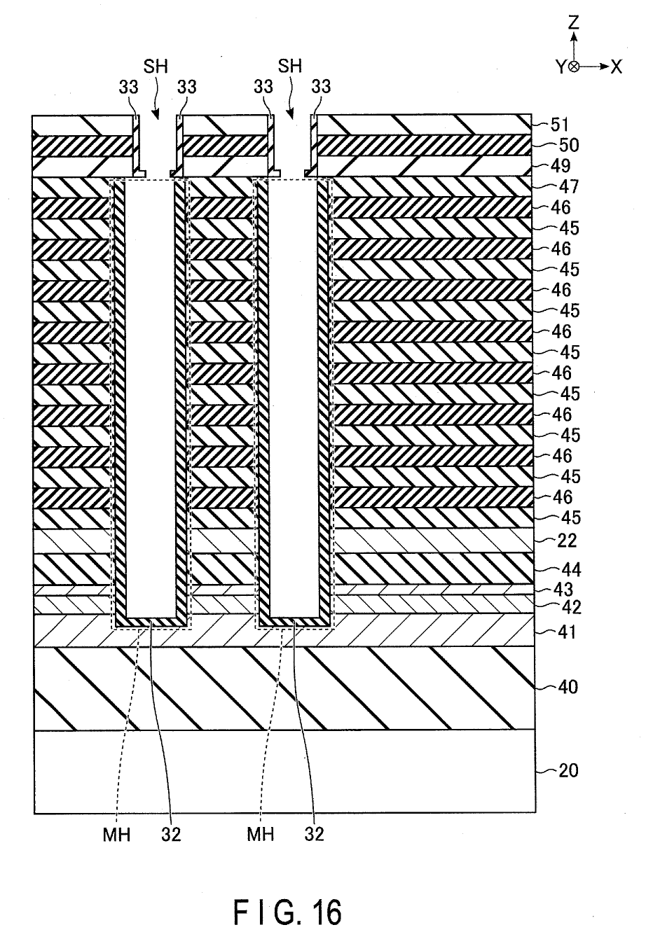

Next, the processing of step S109 is performed to remove the sacrificial member 48 in the memory holes MH. Specifically, the sacrificial member 48 in the memory holes MH is removed by, for example, wet etching, as shown in FIG. 16. Depending on the material used for the sacrificial member 48 and the material used for the passivation film 52, the passivation film 52 may also be removed together in this step.

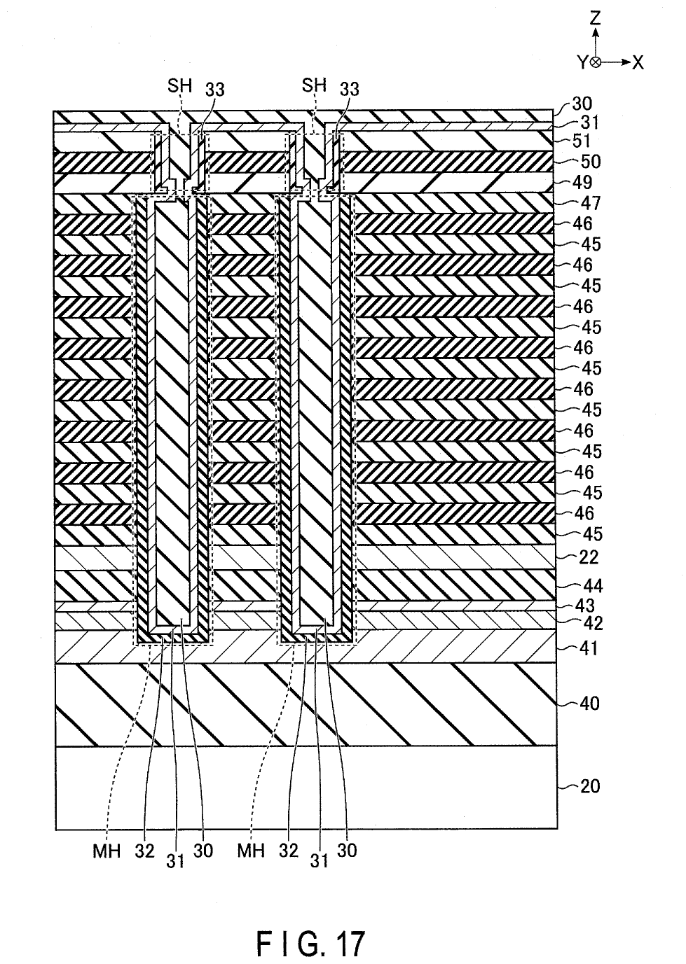

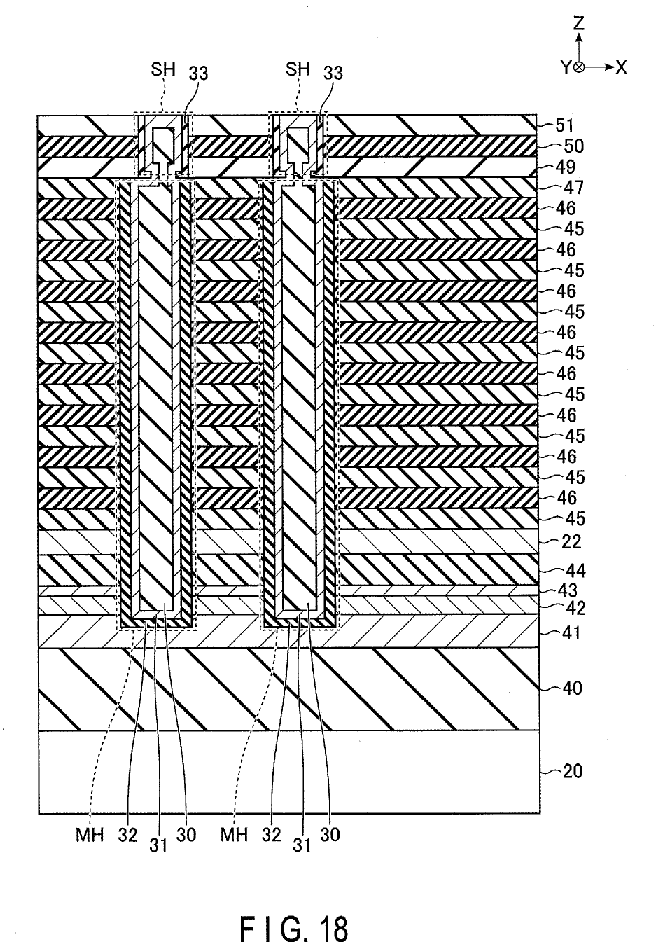

Next, the processing of step S110 is performed to form the semiconductor layer 31 and the core member 30. Specifically, as shown in FIG. 17, first, the semiconductor layer 31 is formed continuously in the memory hole MH and SGD hole SH, and the memory hole MH and the SGD hole SH are filled with an insulator (core member 30). Subsequently, as shown in FIG. 18, first, the core member 30 formed at an upper portion of the SGD hole is removed by etchback, and the area from which the core member 30 is removed is filled with a semiconductor member similar to the semiconductor layer 31. Then, the semiconductor layer 31 and the core member 30 formed in a higher layer than the insulation layer 51 are removed by CMP, for example. As a result, a structure is formed in which the core member 30 is covered with the semiconductor layer 31.

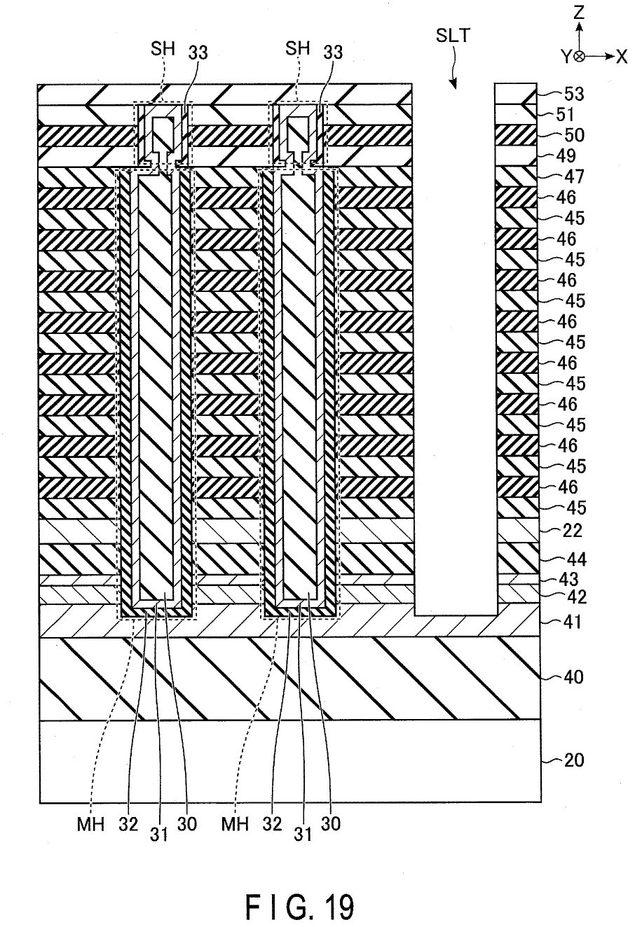

Next, the processing of step S111 is performed to form slits SLT. Specifically, as shown in FIG. 19, first, an insulation layer 53 is formed on the insulation layer 51 and the structure in the SGD hole SH. A mask in which areas corresponding to the slits SLT are opened is formed by photolithography, etc. Then, the slits SLT are formed by anisotropic etching using the formed mask.

Each of the slits SLT formed in this step divides each of the insulation layers 44, 45, 47, 49, 51, and 53, the sacrificial members 42, 46, and 50, and the conductive layers 22 and 43. The bottom of each of the slits SLT stops inside a layer where the conductive layer 41 is provided, for example. It suffices that the bottom of each of the slits SLT reaches a layer where at least the sacrificial member 42 is formed. The anisotropic etching in this step is RIE (Reactive Ion Etching), for example.

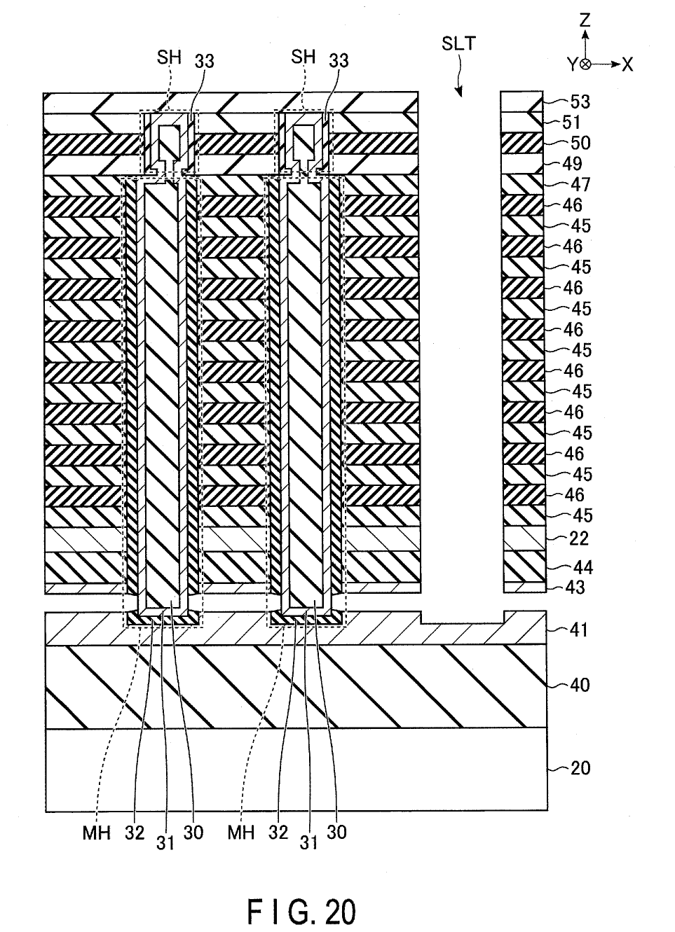

Next, the processing of step S112 is performed to deliver replacement processing of the source line section. Specifically, as shown in FIG. 20, first, the sacrificial member 42 is selectively removed by wet etching via the slits SLT. At this time, a part of the multi-layered film 32 is removed through the area from which the sacrificial member 42 is removed, and parts of the side surfaces of the semiconductor layer 31 are exposed. The structure from which the sacrificial member 42 is removed maintains its three-dimensional structure by, for example, a plurality of memory pillars MP.

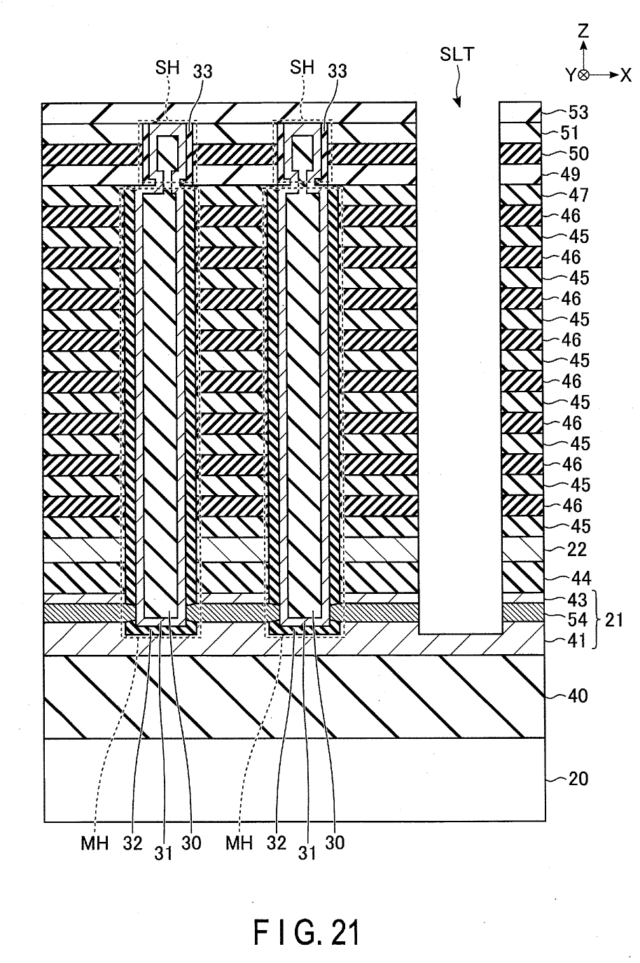

Subsequently, as shown in FIG. 21, the space from which the sacrificial member 42 is removed is filled with a conductive layer 54 by, for example, CVD (Chemical Vapor Deposition). The conductive layer 54 is formed of polysilicon doped with phosphorus, for example. Then, the conductive layer 54 formed inside the slit SLT and on the top surface of the insulation layer 53 is removed by etchback processing.

By taking this step, the semiconductor layer 31 in the memory pillar MP is electrically coupled to a set of the conductive layers 41, 54, and 43. The set of the conductive layers 41, 54, and 43 corresponds to the conductive layer 21 described with reference to FIG. 4, and is used as the source line SL.

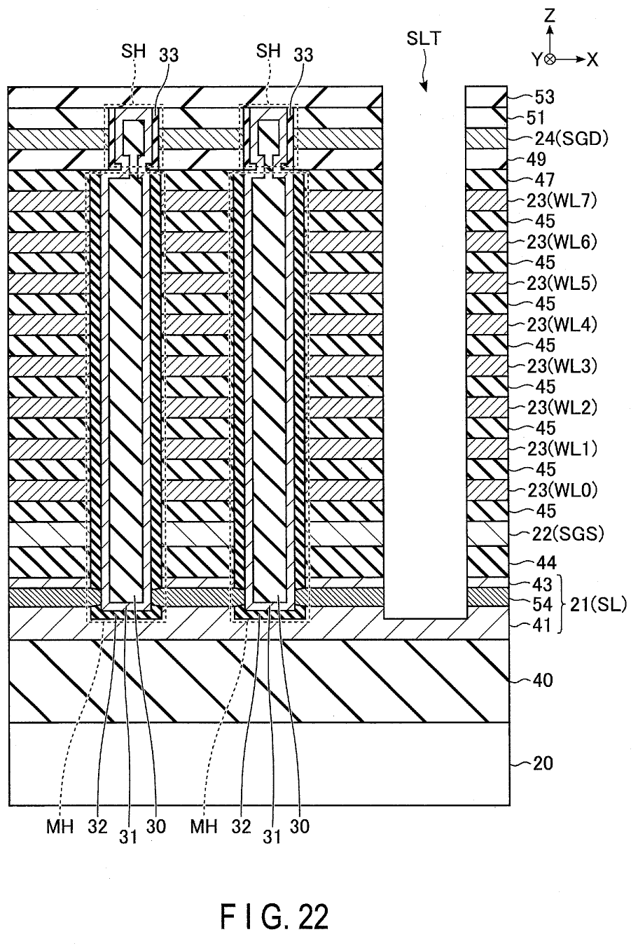

Next, the processing of step S113 is performed to deliver replacement processing of word line sections with a select gate line section. Specifically, as shown in FIG. 22, first, the surfaces of the conductive layers 41, 54, and 43 exposed inside the slit SLT are oxidized to form an oxide protective film (not shown). Afterwards, sacrificial members 46 and 50 are selectively removed by, for example, wet etching by hot phosphoric acid. The structure from which the sacrificial members 46 and 50 are removed maintains its three-dimensional structure by, for example, the plurality of memory pillars MP.

Then, the space from which the sacrificial members 46 and 50 are removed is filled with conductors by, for example, CVD. Subsequently, the conductors formed inside the slit SLT and on the top surface of the insulation layer 53 are removed by etchback processing. Thus, the conductive layers 23, respectively corresponding to word lines WL0 to WL7, and the conductive layer 24, corresponding to the select gate line SGD, are formed. The conductive layers 23 and 24 formed in this step may include a barrier metal. In this case, in the formation of conductors after removal of the sacrificial members 46 and 50, a film of titanium nitride (TiN) is formed as a barrier metal, and thereafter tungsten (W) is formed, for example. Also, the space from which the sacrificial members 46 and 50 are removed may be filled with conductors via an insulator, which serves as a block insulation film of the memory cell transistor MT or the select transistor ST1 together with the block insulation films 36 and 39 in the multi-layered films 32 and 33.

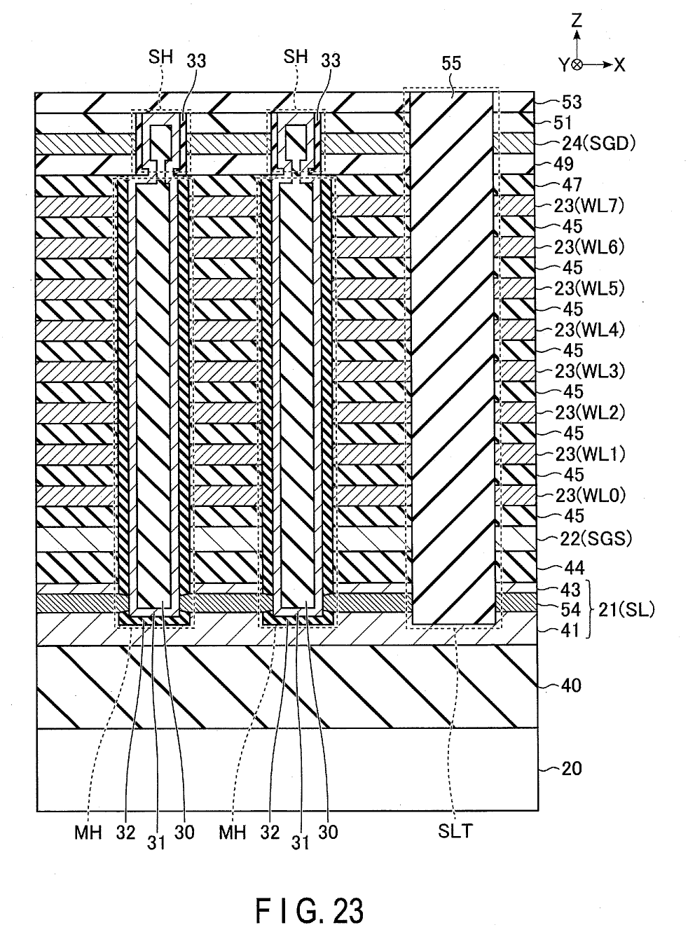

Next, the processing of step S114 is performed to form an insulator 55 in the slit SLT. Specifically, as shown in FIG. 23, first, the insulator 55 is formed on the top surface of the insulation layer 53, and the slit SLT is filled with the insulator 55. Afterwards, the insulator 55 formed outside the slit SLT is removed by, for example, CMP. As a result, a structure in which the slit SLT is filled with the insulator 55 is formed. The insulator 55 includes oxide silicon (SiO₂), for example.

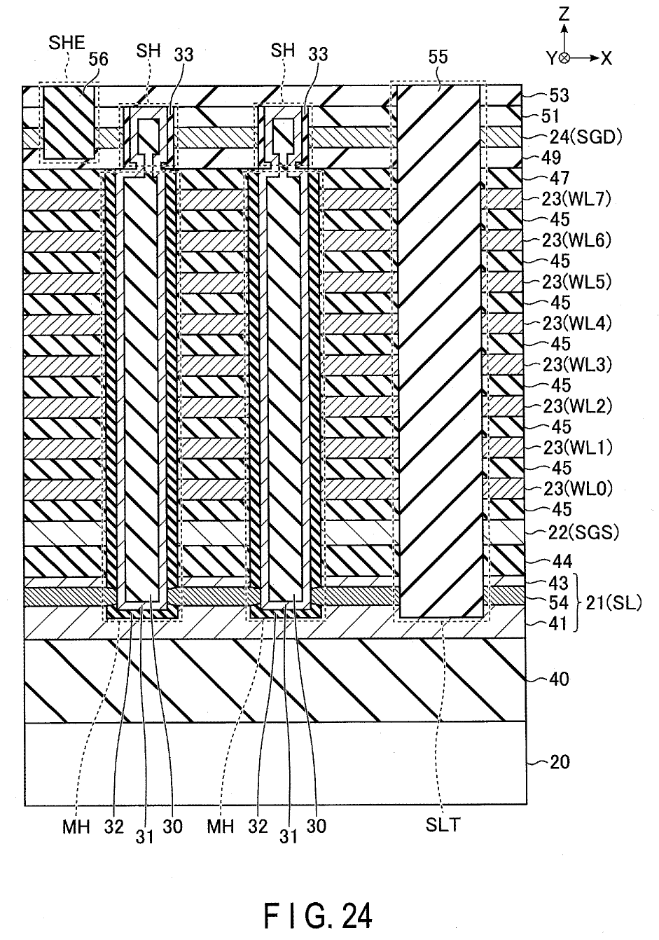

Next, the processing of step S115 is performed to form a slit SHE. Specifically, as shown in FIG. 24, first, a mask in which an area corresponding to the slit SHE is opened is formed by photolithography, etc. Then, a slit SHE is formed by anisotropic etching using the formed mask.

The slit SHE formed in this step divides the conductive layer 24, and the bottom of the slit SHE stops inside a layer where the insulation layer 49 is formed. The bottom of the slit SHE may reach the insulation layer 47 within a scope where this has no influence on the characteristics of the NAND strings NS. The anisotropic etching in this step is RIE, for example.

Afterwards, an insulator 56 is formed on the insulation layer 53, and the slit SHE is filled with the insulator 56. The insulator 56 formed outside the slit SHE is removed by, for example, CMP. As a result, a structure in which the slit SHE is filled with the insulator 56 is formed. The insulator 56 includes oxide silicon (SiO₂), for example.

By the above-described manufacturing steps of the semiconductor memory device 1 according to the first embodiment, the memory pillar MP, the source line SL and word line WL coupled to the memory pillar MP, and select gate lines SGS and SGD are respectively formed. The manufacturing steps described above are a mere example, and another process may be inserted between any of the manufacturing steps, and the order of the manufacturing steps may be changed within a scope where it causes no problem.

[1-3] Advantageous Effects of First Embodiment

The semiconductor memory device 1 according to the first embodiment described above can reduce manufacturing costs of the semiconductor memory device 1. Hereinafter, detailed advantageous effects of the semiconductor memory device 1, according to the first embodiment, will be described.

In a semiconductor memory device in which memory cells are three-dimensionally stacked, sheet-like wires used as word lines WL are stacked, and a structure for functioning as a memory cell transistor MT is formed in the memory pillar that penetrates the multi-layered wires. In such a semiconductor memory device, for example, a plate-like select gate line SGD is formed, through which the memory pillars pass similarly to the word lines, and the operation in page units is realized by appropriately dividing the select gate line SGD. In order to increase a storage capacity per unit area of the semiconductor memory device, it is preferable to increase a positional density of the memory pillars.

However, if the positional density of the memory pillars is simply increased, it becomes difficult to form a slit SHE dividing the select gate line SGD without overlapping with memory pillars MP arranged with a high density. If a slit SHE and a memory pillar MP are in contact with each other, the variations in characteristics of the select transistor ST1 may increase, leading to unstable operations. For this reason, the slit SHE and the memory pillars MP are preferably formed separately from each other.

In contrast, the semiconductor memory device 1 according to the first embodiment has a structure in which a memory pillar MP is formed in two divided portions (a portion corresponding to the memory hole MH and a portion corresponding to the SGD hole SH). Then, in the semiconductor memory device 1 according to the first embodiment, the diameter of the SGD hole SH is designed to be smaller than the diameter of the memory hole MH, the two portions constituting the memory pillar MP have cross-sectional areas differing in size from each other, and the positional relationship between the corresponding memory hole MH and SGD hole SH is changed in accordance with the positional relationship between the slits SLT and SHE.

Thus, in the semiconductor memory device 1 according to the first embodiment, structures corresponding to the memory holes MH can be arranged with a high density, and structures corresponding to the SGD holes SH away from the slits SHE can be formed. As a result, the semiconductor memory device 1 according to the first embodiment can increase the storage capacity per unit area, and allows formation of more semiconductor memory devices 1 per sheet of silicon wafer, for example. Therefore, the semiconductor memory device 1 according to the first embodiment allows reduction in the manufacturing costs of the semiconductor memory device 1.

Furthermore, in the manufacturing steps of the semiconductor memory device 1 according to the first embodiment, the multi-layered film 32 in the memory hole MH and the multi-layered film 33 in the SGD hole SH are formed in different steps. In other words, in the semiconductor memory device 1 according to the first embodiment, the layer structure of an insulation film used for the memory cell transistor MT can be made to differ from the layer structure of an insulation film used for the select transistor ST1. For example, the select transistor ST1 is not used for storing data, and thus thicknesses of various insulation films (tunnel insulation film 37, insulation film 38, and block insulation film 39) included in the multi-layered film 33 can be thinner than that of the multi-layered film 32.

As a result, in the semiconductor memory device 1 according to the first embodiment, the diameter of the SGD hole SH can be reduced, and the degree of freedom of the layout of each of the memory hole MH and SGD hole SH can be increased. Then, the semiconductor memory device 1 according to the first embodiment also allows for reduction in costs in the forming of the multi-layered film 33.

Furthermore, in the manufacturing steps of the semiconductor memory device 1 according to the first embodiment, the semiconductor layer 31 in the memory hole MH and the semiconductor layer 31 in the SGD hole are formed in block during the same manufacturing step. In other words, in the semiconductor memory device 1 according to the first embodiment, the semiconductor layer 31 in the memory hole MH and the semiconductor layer 31 in the SGD hole SH are continuously formed.

With this configuration, in the semiconductor memory device 1 according to the first embodiment, the channel resistance of NAND strings NS can be reduced as compared to the case where the semiconductor layer 31 in the memory hole MH and the semiconductor layer 31 in the SGD hole SH are formed in different steps. Additionally, the semiconductor memory device 1 according to the first embodiment can prevent occurrences of defects that would be caused when the semiconductor layer 31 in the memory hole MH and the semiconductor layer 31 in the SGD hole SH are formed in different steps.

As described above, the semiconductor memory device 1 according to the first embodiment can prevent occurrences of defects attributable to the memory pillar MP, and can also prevent an increase in the manufacturing steps. Therefore, the manufacturing method of the semiconductor memory device 1 according to the first embodiment can increase the yield of the semiconductor memory device 1 and reduce the manufacturing costs.

### [2] Second Embodiment

A semiconductor memory device 1 according to a second embodiment differs in the structure of the semiconductor layer 31 in the memory pillar MP from the semiconductor memory device 1 according to the first embodiment. In the following, differences between the semiconductor memory device 1 of the second embodiment and that of the first embodiment will be described.

[2-1] Structure of Memory Cell Array 10

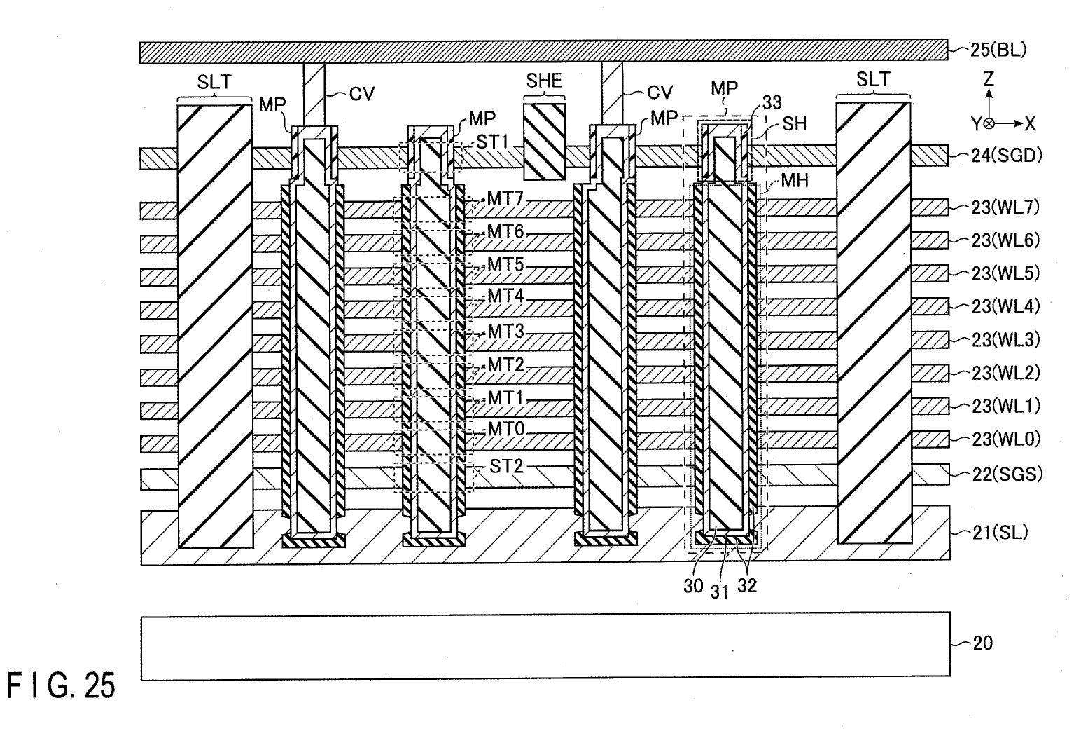

FIG. 25 shows an example of a cross-sectional structure of a memory cell array 10 included in the semiconductor memory device 1 according to the second embodiment. As shown in FIG. 25, the structure of the memory cell array 10 according to the second embodiment differs in the structure of a memory pillar MP from the structure of the memory cell array 10, explained with reference to FIG. 4.

Specifically, the memory pillar MP in the second embodiment differs in the structures of a core member 30 and a semiconductor layer 31 in a border portion between a memory hole MH and an SGD hole SH. The semiconductor layer 31 in the second embodiment has a portion provided on the bottom surface of a multi-layered film 33 in the SGD hole SH. Furthermore, depending on the positional relationship between a memory hole MH and an SGD hole SH corresponding to each other, the semiconductor layer 31 may be in contact with the top surface of the multi-layered film 32 in the memory hole MH.

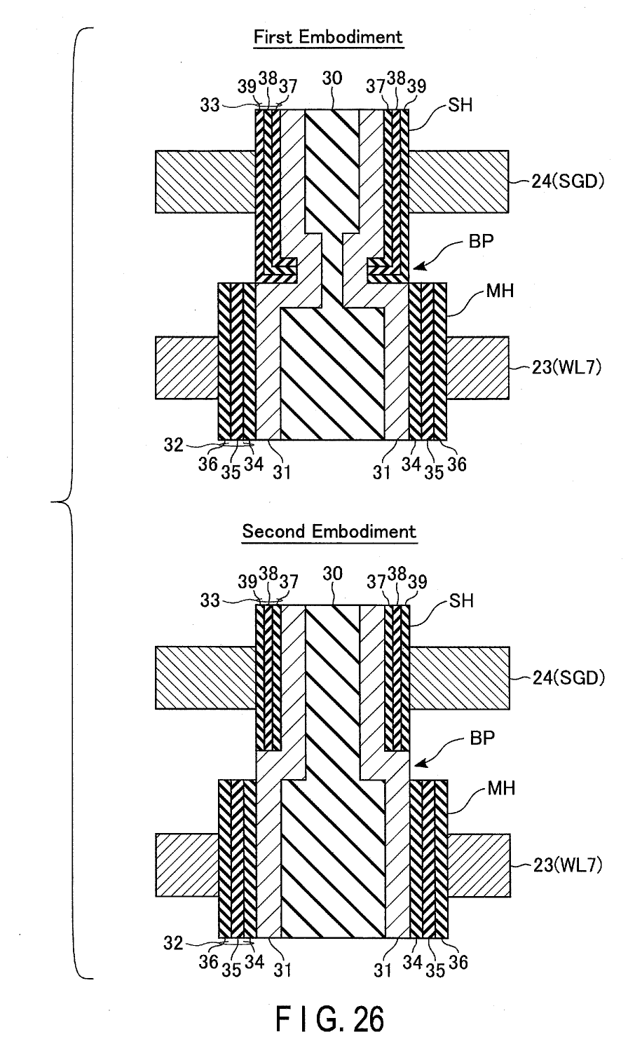

In the following, detailed differences between the structure of the memory pillar MP in the first embodiment and the structure of the memory pillar MP in the second embodiment will be described with reference to FIG. 26. FIG. 26 shows detailed cross-sectional structures of the memory pillars MP of the first and second embodiments, respectively. In the following, the bottom of the structure in the SGD hole SH is referred to as a “connected portion BP”.

As shown in FIG. 26, in the memory pillar MP in the first embodiment, the multi-layered film 33 (tunnel insulation film 37, insulation film 38, and block insulation film 39) in the connected portion BP has a portion extending toward a center portion in the SGD hole SH. Then, the semiconductor layer 31 in the memory pillar MP has a portion constricted along that portion. The bottom of the laminated film 33 in this structure has a structure where the block insulation film 39, the insulation film 38, and the tunnel insulation film 37 are stacked in this order, and at the bottom of the multi-layered film 33, only the block insulation film 39 is in contact with the semiconductor layer 31.

On the other hand, in the memory pillar MP in the second embodiment, the multi-layered film 33 in the connected portion BP does not have a portion extending toward a center portion in the SGD hole SH, for example. For this reason, the semiconductor layer 31 in the memory pillar MP does not have any constricted portions in the connected portion BP, as compared to the first embodiment. At the bottom of the multi-layered film 33 in this structure, the tunnel insulation film 37, the insulation film 38, and the block insulation film 39 are respectively in contact with the semiconductor layer 31, for example.

The structure of the memory pillar MP in the second embodiment is not limited thereto, and it is sufficient that at least the semiconductor layer 31 does not include any constricted portions in the connected portion BP. Additionally, in the memory pillar MP in the second embodiment, it is preferable that the multi-layered film 32 in the memory hole MH be separated in the Z-axis direction from the multi-layered film 33 in the SGD hole SH.

Based on the structures of the multi-layered film 33 and the semiconductor layer 31 explained above, for example, in the core member 30 in the first embodiment, a structure is formed which has a portion constricted along the multi-layered film 33 in the connected portion BP. On the other hand, in the core member 30 in the second embodiment, a structure is formed which does not have any portions constricted along the multi-layered film 33 in the connected portion BP. Explanations on the other structures in the semiconductor memory device 1 according to the second embodiment are omitted because the other structures are the same as those in the semiconductor memory device 1 according to the first embodiment.

[2-2] Manufacturing Method of Semiconductor Memory Device 1

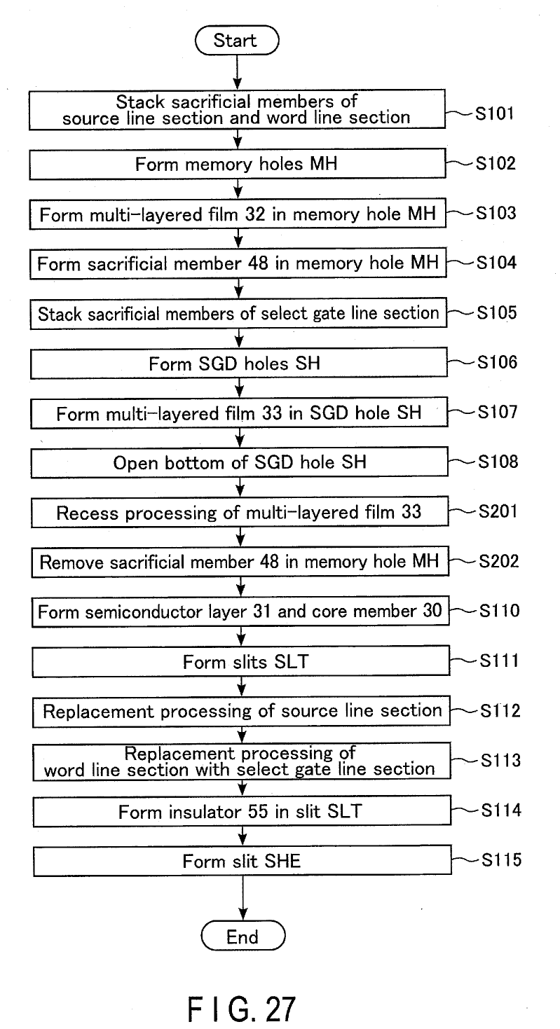

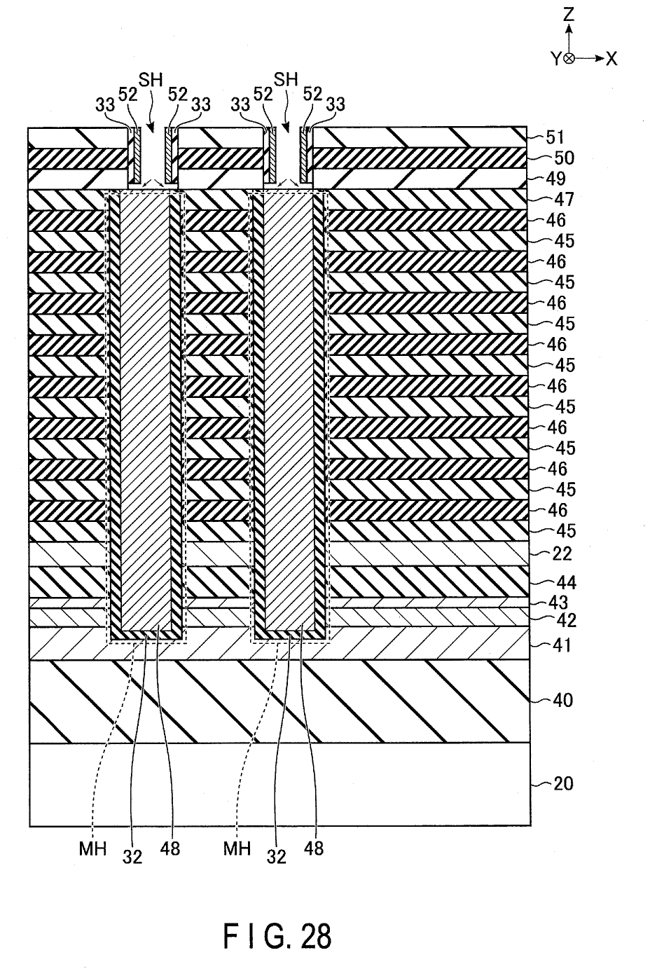

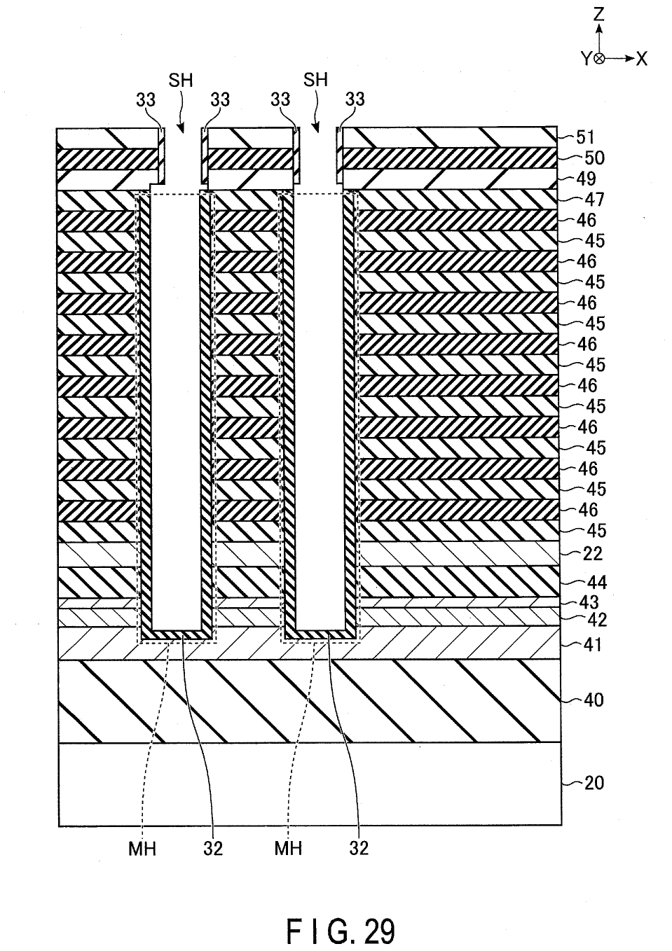

In the following, with reference to FIG. 27, an example of a series of manufacturing steps from the formation of a multi-layered structure corresponding to a source line SL to the formation of a slit SHE in the semiconductor memory device 1, according to the second embodiment, will be described. FIG. 27 is a flowchart showing an example of a manufacturing method of the semiconductor memory device 1 according to the second embodiment. Each of FIGS. 28 and 29 shows an example of a cross-sectional structure including a structure corresponding to a memory cell array 10 in the manufacturing steps of the semiconductor memory device 1 according to the second embodiment.

As shown in FIG. 27, in the manufacturing method of the semiconductor memory device 1 according to the second embodiment, the processing of step S109 in the manufacturing method explained using FIG. 7 is replaced with the processing of step S S201 and S202.

Specifically, first, the processing of steps S101 to S108 is sequentially performed, similarly to the first embodiment. As a result, a structure in which the bottom of the SGD hole SH is opened is formed similarly to FIG. 15 referred to in the first embodiment.

Next, the processing of step S201 is performed to deliver recess processing of the multi-layered film 33. Specifically, as shown in FIG. 28, a part of the exposed multi-layered film 33 is removed by, for example, CDE (Chemical Dry Etching). In this step, the multi-layered film 33, formed in a lower layer than the bottom of a passivation film 52, is preferably removed, and it is sufficient to at least remove the multi-layered film 33 formed at the bottom of the passivation film 52.

Next, the processing of step S202 is performed to remove a sacrificial member 48 in the memory holes MH. Specifically, as shown in FIG. 29, the sacrificial member 48 in the memory hole MH is removed by, for example, wet etching. Similarly to the first embodiment, depending on a material used for the sacrificial member 48 and a material used for the passivation film 52, the passivation film 52 may also be removed together in this step. Also, in this step, a condition where an etching selection ratio is low with respect to the insulation layer 49 is used.

Then, the processing of step S110 to S115 is performed sequentially, similarly to the first embodiment. As a result, structures of conductive layers 21 to 24, memory pillars MP, and slits SLT and SHE in the second embodiment (shown in FIGS. 25 and 26) are formed. Explanations on the other manufacturing method of the semiconductor memory device 1 according to the second embodiment are omitted because the details thereof are the same as the manufacturing method of the semiconductor memory device 1, according to the first embodiment.

[2-3] Advantageous Effects of Second Embodiment

As described above, the semiconductor memory device 1, according to the second embodiment, is formed so as not to include a structure in which the semiconductor layer 31 in a memory pillar MP is constricted. In other words, in the semiconductor memory device 1 according to the second embodiment, a significant change in curvature of the semiconductor layer 31 in the connected portion BP is suppressed.

With this configuration, the semiconductor memory device 1 according to the second embodiment allows for formation of the semiconductor layer 31 in a more stable manner than the first embodiment. Therefore, the semiconductor memory device 1 according to the second embodiment can further increase a yield thereof and suppress the manufacturing costs of the semiconductor memory device 1 as compared to the first embodiment.

### [3] Third Embodiment

A semiconductor memory device 1 according to a third embodiment differs in a connected structure between a semiconductor layer 31, inside a memory hole MH, and a conductive layer 21, from the semiconductor memory device 1 according to the first embodiment. In the following, differences between the semiconductor memory device 1 according to the third embodiment and that of the first embodiment will be described.

[3-1] Structure of Memory Cell Array 10

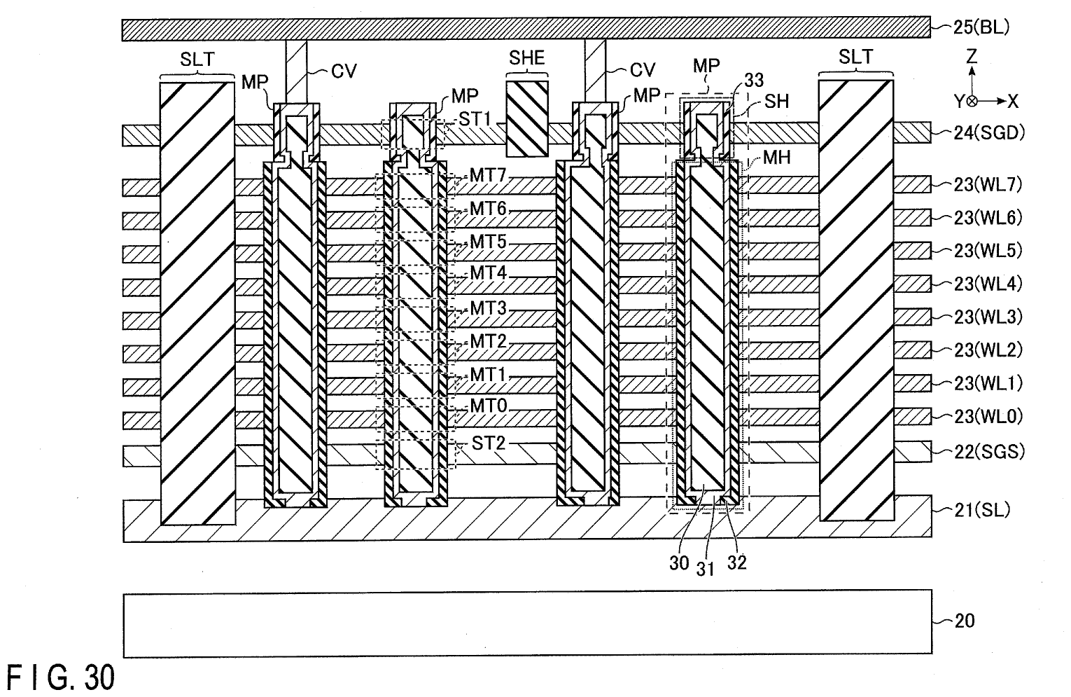

FIG. 30 shows an example of a cross-sectional structure of a memory cell array 10 included in the semiconductor memory device 1 according to the third embodiment. As shown in FIG. 30, the structure of the memory cell array 10 in the third embodiment differs from that explained with reference to FIG. 4 in the first embodiment with respect to the structure of a memory pillar MP.

Specifically, in the memory pillar MP in the first embodiment, the conductive layer 21 is in contact with the side surface of the semiconductor layer 31, whereas in the memory pillar MP in the third embodiment, the conductive layer 21 is in contact with the bottom of a semiconductor layer 31. For this reason, in the manufacturing step of the memory pillar MP in the third embodiment, a part of the bottom of the multi-layered film 32 is removed, and the semiconductor layer 31 is formed in the part of the bottom from which the multi-layered film 32 is removed. Explanations on the other structures in the semiconductor memory device 1 according to the third embodiment are omitted because the other structures are the same as those in the semiconductor memory device 1 according to the first embodiment.

[3-2] Advantageous Effects of Third Embodiment

As described above, in the semiconductor memory device 1 according to the third embodiment, the semiconductor layer 31 and the conductive layer 21 are electrically coupled in the bottom of the memory pillar MP. Even in such a structure, the semiconductor memory device 1 allows for formation of a current pathway of NAND strings NS, similarly to the first embodiment. The other advantageous effects of the semiconductor memory device 1, according to the third embodiment are the same as those of the semiconductor memory device 1 according to the first embodiment.

### [4] Fourth Embodiment

A semiconductor memory device 1 according to a fourth embodiment differs from the semiconductor memory device 1 according to the first embodiment with respect to the structure of a select transistor ST1. In the following, differences between the semiconductor memory device 1 according to the fourth embodiment and that of the first embodiment will be described.

[4-1] Structure of Memory Cell Array 10

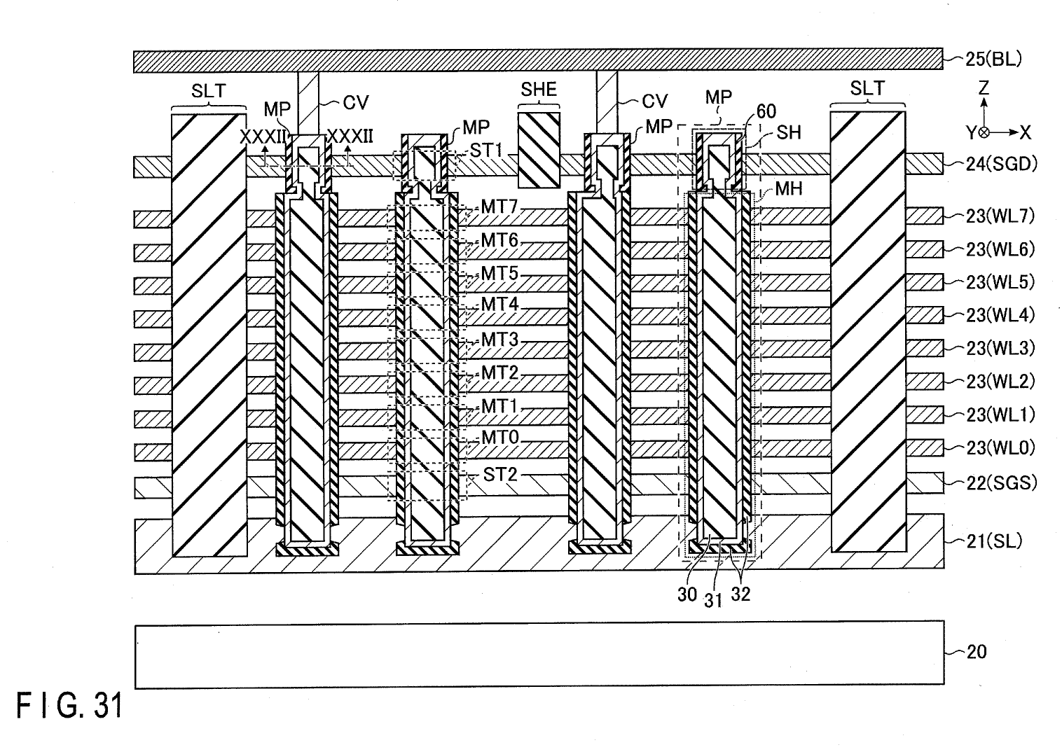

FIG. 31 shows an example of a cross-sectional structure of a memory cell array 10 included in the semiconductor memory device 1 according to the fourth embodiment. As shown in FIG. 31, the structure of the memory cell array 10 in the fourth embodiment differs from that of the memory cell array 10, explained with reference to FIG. 4 in the first embodiment, with respect to the structure of a memory pillar MP.

Specifically, in the memory pillar MP in the first embodiment, the multi-layered film 33 is formed in the SGD hole SH, whereas in the memory pillar MP in the fourth embodiment, a single-layered gate insulation film 60 is formed in place of the multi-layered film 33. The gate insulation film 60 is used as a gate insulation film 60 for a select transistor ST1. The thickness of the gate insulation film 60 may be equal to the thickness of the multi-layered film 33 in the first embodiment, or may be thinner than the thickness of the multi-layered film 32 in the memory hole MH.

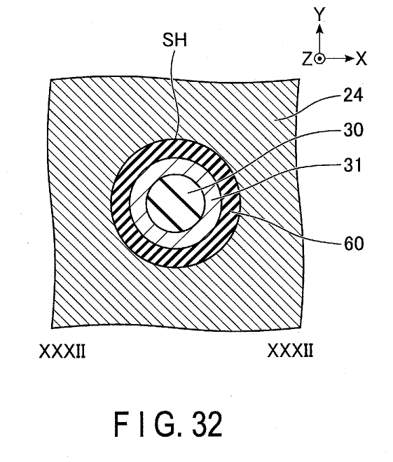

FIG. 32 is a cross-sectional view taken along an XXII-XXII line in FIG. 31, and shows an example of a cross-sectional structure of the memory pillar MP in the semiconductor memory device 1 according to the fourth embodiment. More specifically, FIG. 32 shows a cross-sectional structure in a portion corresponding to an SGD hole SH of a memory pillar MP in the layer which is parallel to the surface of the semiconductor substrate 20 and which includes the conductive layer 24.

As shown in FIG. 32, in the layer including the conductive layer 24, the core member 30 is provided in a center portion of the SGD hole SH. The semiconductor layer 31 surrounds the side surface of the core member 30. The gate insulation film 60 surrounds the side surface of the semiconductor layer 31. The gate insulation film 60 is formed using the same material as that of a tunnel insulation film 34 in the multi-layered film 32, for example. The gate insulation film 60 includes silicon oxide (SiO₂), for example. Explanations on the other structures in the semiconductor memory device 1 according to the fourth embodiment are omitted because the other structures are the same as those in the semiconductor memory device 1 according to the first embodiment.

[4-2] Advantageous Effects of Fourth Embodiment

As described above, in the semiconductor memory device 1 according to the fourth embodiment, the gate insulation film 60 is formed into a single-layer in the SGD hole SH. Even in the structure where the gate insulation film 60 in the SGD hole SH does not have a charge storage layer in such a manner, a portion where the structure in the SGD hole SH crosses a select gate line SGD can operate as a select transistor ST1 that is not used for storing data. The other advantageous effects of the semiconductor memory device 1, according to the fourth embodiment, are the same as those of the semiconductor memory device 1 according to the first embodiment.

### [5] Modifications

A semiconductor memory device according to an embodiment includes a plurality of first conductive layers, a second conductive layer, a first pillar, and a second pillar. The first conductive layers are stacked in a first direction above a substrate. The first conductive layers are separated from each other. The second conductive layer is provided above the first conductive layers. The first pillar is provided so as to penetrate the first conductive layers. The first pillar includes one part of a first semiconductor layer extending in the first direction, and a portion where the first pillar crosses each of the first conductive layers functions as a memory cell transistor. The second pillar penetrate the second conductive layer and is provided on the first pillar. The second pillar includes another part of the first semiconductor layer, and a portion where the second pillar crosses the second conductive layer functions as a select transistor. An area of the second pillar in a cross-section parallel to the substrate and including the second conductive layer is smaller than an area of the first pillar in a cross-section parallel to the substrate and including one of the first conductive layers. The first semiconductor layer includes a first portion facing an uppermost one of the first conductive layers and a second portion facing the second conductive layer. The first semiconductor layer is continuous at least from the first portion to the second portion. With the configuration described above, the manufacturing costs of the semiconductor memory device can be suppressed.

The embodiments described above can be suitably combined with each other. For example, the second embodiment can be combined with each of the third embodiment and the fourth embodiment. The third embodiment can be combined with the fourth embodiment.

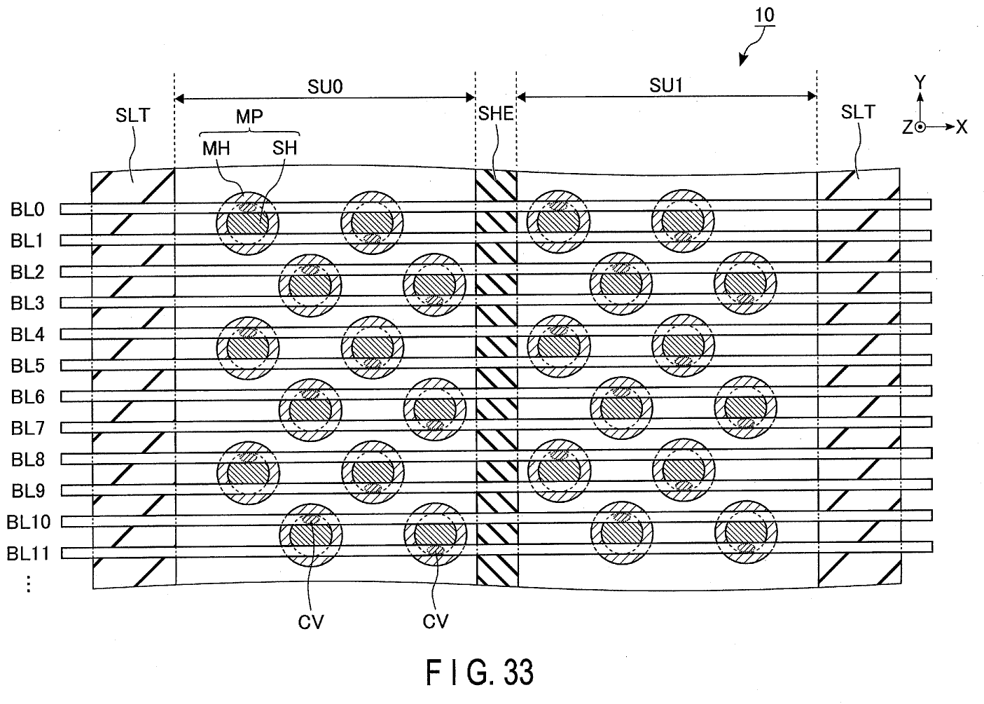

In the above embodiments, the case is exemplified where the positional relationship between a memory hole MH and a SGD hole SH, corresponding to each other, varies according to the positional relationship between slits SLT and SHE. However, the configuration is not limited thereto. FIG. 33 shows an example of a planar layout of a memory cell array 10 included in a semiconductor memory device 1, according to a modification of the first embodiment. As shown in FIG. 33, in the planar layout of the memory cell array 10, a center of a corresponding memory hole MH may not necessarily be shifted with a center of a corresponding SGD hole SH.

In the semiconductor memory device 1 according to the modification of the first embodiment, a structure can be formed whereby a space between the slits SLT and SHE and each of the SGD holes SH is separated by forming the diameter of each of the SGD holes SH to be smaller than the diameter of each of the memory holes MH. The semiconductor memory device 1, even when provided with such a structure as that in the modification of the first embodiment can obtain the same advantageous effects as those of the embodiments described above.

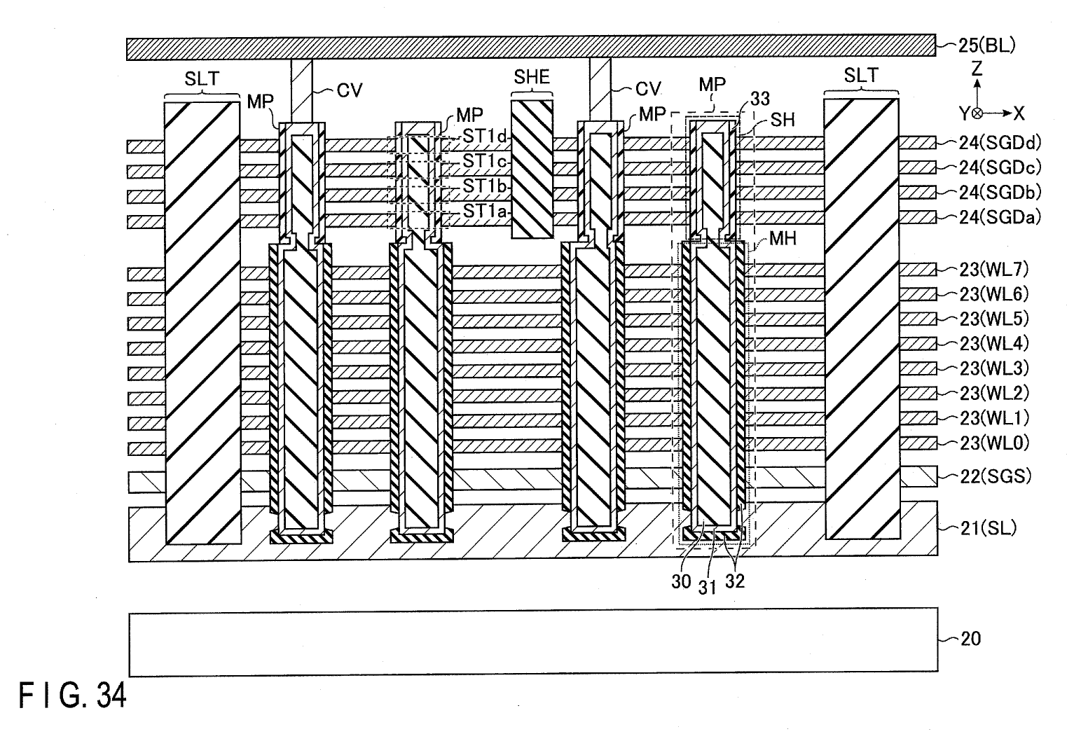

In the above embodiments, the case is exemplified where one conductive layer 24 penetrated by the SGD hole SH is present. However, the configuration is not limited thereto. FIG. 34 shows an example of a cross-sectional structure of the memory cell array 10 included in the semiconductor memory device 1 according to the modification of the first embodiment. As shown in FIG. 34, in the cross-sectional structure of the memory cell array 10, the SGD hole SH may penetrate a plurality of conductive layers 24. More specifically, a portion of each memory pillar MP corresponding to each of the SGD holes SH penetrates, for example, four conductive layers 24.

These conductive layers 24 are used, for example, as select gate lines SGDa, SGDb, SGDc, and SGDd, in sequence from the lowest layer thereof. In each memory pillar MP, a portion where the SGD hole SH crosses the select gate line SGDa functions as a select transistor ST1a; a portion where the SGD hole SH crosses the select gate line SGDb functions as a select transistor ST1b; a portion where the SGD hole SH crosses the select gate line SGDc functions as a select transistor ST1c; and a portion where the SGD hole SH crosses the select gate line SGDd functions as a select transistor ST1d, for example. The select gate lines SGDa, SGDb, SGDc, and SGDd may be controlled either independently or in a block. As described above, a plurality of layers of the select gate line SGD may be formed in the semiconductor memory device 1.

In the above embodiments, the structure of the memory cell array 10 may be another different structure. For example, in the structure of the memory pillar MP, a plurality of pillars may be connected along the Z-axis direction. In this case, in the structure of the memory pillar MP, for example, a pillar penetrating the conductive layer 24 (the select gate line SGD) and the plurality of conductive layers 23 (the word lines WL) may be connected to a pillar penetrating the plurality of conductive layers 23 (the word lines WL) and the conductive layer 22 (the select gate line SGS). Furthermore, the memory pillar MP may include a plurality of pillars each penetrating the plurality of conductive layers 23.

In the above embodiments, the case is described as an example where a circuit, such as the sense amplifier module 16, is provided below the memory cell array 10 in the structure of the semiconductor memory device 1. However, the configuration is not limited thereto. For example, in the structure of the semiconductor memory device 1, the memory cell array 10 and the sense amplifier module 16 may be formed on the semiconductor substrate 20. In this case, the memory pillar MP is formed in the structure described in the third embodiment, for example. The semiconductor memory device 1 may have a structure where a chip provided with the sense amplifier module 16, etc. is bonded to a chip provided with the memory cell array 10.

In the above embodiments, a structure is described where a word line WL is adjacent to a select gate line SGS, and the word line WL is adjacent to a select gate line SGD. However, the configuration is not limited thereto. For example, a dummy word line may be provided between the uppermost layer of the word lines WL and the select gate line SGD. Similarly, a dummy word line may be provided between the lowest layer of the word lines WL and the select gate line SGS. In the case where a plurality of pillars are connected to each other, a conductive layer in the vicinity of each connected portion thereof may be used as a dummy word line.

In the drawings used for explanations in the above embodiments, the case is exemplified where the outer diameters of the memory hole MH and the SGD hole SH are fixed regardless of the stacked positions thereof. However, the configuration is not limited thereto. For example, the memory hole MH and the SGD hole SH may have a tapered shape, or a shape where a center portion thereof swells. Similarly, the slits SLT and SHE may have a tapered shape, or a shape where a center portion thereof swells.

In this specification, the term “coupled” means an electrical coupling, and does not exclude a coupling with an element being interposed in the coupling, for example. The phrase “provided continuously” indicates the act of something being formed in the same manufacturing step. Portions provided continuously in a structural element do not have a border therebetween. Furthermore, the phrase “provided continuously” denotes being a continuous film from a first portion to a second portion in a film or a layer. The term “thickness” indicates the difference between the inner diameter and the outer diameter of the structural element formed in the memory hole MH or the SGD hole SH, for example. The term “inner diameter” and the term “outer diameter” respectively indicate an inner diameter and an outer diameter of a cross-section area parallel to the semiconductor substrate 20.

In this specification, the term “portion facing” corresponds to portions of two adjacent structural elements in the direction parallel to the surface of the semiconductor substrate 20. For example, a portion of the semiconductor layer 31 facing the conductive layer 23 corresponds to a portion of the semiconductor layer 31 included in a layer where the conductive layer 23 is formed. The expression “the thickness is approximately equal to” indicates a layer (film) formed in the same manufacturing step, and encompasses variations based on the film-formed positions.

The term “pillar-shape” in this specification indicates a structure provided in a hole formed in the manufacturing step of the semiconductor memory device 1. The structure formed in each of the memory hole MH and the SGD hole SH may be referred to as a “pillar”. In other words, the memory pillars MP in the above embodiments have a structure whereby a pillar corresponding to each of the SGD holes SH is formed on a pillar corresponding to each of the memory holes MH.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first conductive layers stacked in a first direction above a substrate, the plurality of first conductive layers being separated from each other;
a second conductive layer provided above the first conductive layers;
a first pillar provided so as to penetrate the first conductive layers, the first pillar including one part of a first semiconductor layer extending in the first direction, and a portion where the first pillar crosses each of the first conductive layers functioning as a memory cell transistor; and
a second pillar penetrating the second conductive layer and provided on the first pillar, the second pillar including another part of the first semiconductor layer, and a portion where the second pillar crosses the second conductive layer functioning as a select transistor,
wherein an area of the second pillar in a cross-section parallel to the substrate and including the second conductive layer is smaller than an area of the first pillar in a cross-section parallel to the substrate and including one of the first conductive layers, and
wherein the first semiconductor layer includes a first portion facing an uppermost one of the first conductive layers and a second portion facing the second conductive layer, and the first semiconductor layer is continuous at least from the first portion to the second portion.

2. The device of claim 1, wherein a space between the uppermost one of the first conductive layers and the second conductive layer in the first direction is wider than a space between two adjacent layers of the first conductive layers in the first direction.

3. The device of claim 1, wherein in a plan view, a center of the first pillar does not overlap a center of the second pillar.

4. The device of claim 1, wherein
the first pillar further comprises a first multi-layered film provided between the first semiconductor layer and the first conductive layers,
the second pillar further comprises a second multi-layered film provided between the first semiconductor layer and the second conductive layer, and
at least a portion of the first multi-layered film is separated from the second multi-layered film.

5. The device of claim 1, wherein
the first pillar further comprises a first multi-layered film provided between the first semiconductor layer and the first conductive layers,
the second pillar further comprises a second multi-layered film provided between the first semiconductor layer and the second conductive layer, and
a thickness of the second multi-layered film is thinner than a thickness of the first multi-layered film.

6. The device of claim 4, wherein
the first multi-layered film comprises a first charge storage layer, a first tunnel insulation film provided between the first charge storage layer and the first semiconductor layer, and a first block insulation film provided between the first charge storage layer and the first conductive layers, and
the second multi-layered film comprises a second charge storage layer, a second tunnel insulation film provided between the second charge storage layer and the first semiconductor layer, and a second block insulation film provided between the second charge storage layer and the second conductive layer.

7. The device of claim 6, wherein
a bottom surface of the second tunnel insulation film, a bottom surface of the second block insulation film, and a bottom surface of the second charge storage layer are in contact with the first semiconductor layer.

8. The device of claim 1, wherein
the first pillar further comprises a first multi-layered film provided between the first semiconductor layer and the first conductive layers,
the second pillar further comprises a gate insulation film provided between the first semiconductor layer and the second conductive layer, and
the first multi-layered film comprises a charge storage layer, and the gate insulation film does not comprise a charge storage layer.

9. The device of claim 8, wherein
the first multi-layered film comprises a first charge storage layer, a first tunnel insulation film provided between the first charge storage layer and the first semiconductor layer, and a first block insulation film provided between the first charge storage layer and the first conductive layers.

10. The device of claim 9, wherein the gate insulation film is a single-layered film formed of the same material as that of the first tunnel insulation film.

11. The device of claim 8, wherein a thickness of the gate insulation film is thinner than a thickness of the first multi-layered film.

12. The device of claim 8, wherein at least a portion of the first multi-layered film is separated from the gate insulation film.

13. The device of claim 1, wherein
the first pillar further comprises a first multi-layered film provided between the first semiconductor layer and the first conductive layers,
the second pillar further comprises a second multi-layered film or a gate insulation film, provided between the first semiconductor layer and the second conductive layer, and
the first multi-layered film and the second multi-layered film or the gate insulation film is separated from each other in the first direction.

14. The device of claim 1, wherein
the first pillar and the second pillar further comprise a first insulation layer covered with the first semiconductor layer, the first insulation layer extending in the first direction while spanning the first pillar and the second pillar.

15. The device of claim 1, further comprising:
a third conductive layer provided on the same layer where the second conductive layer is provided, the third conductive layer being separated from the second conductive layer;
an insulator provided between the second conductive layer and the third conductive layer;
a third pillar provided so as to penetrate the first conductive layers, the third pillar including one part of a second semiconductor layer extending in the first direction, and a portion where the third pillar crosses each of the first conductive layers functioning as a memory cell transistor; and
a fourth pillar penetrating the third conductive layer and provided on the third pillar, the fourth pillar including another part of the second semiconductor layer other than the part of the second semiconductor layer, and a portion where the fourth pillar crosses the third conductive layer functioning as a select transistor,
wherein
an area of the fourth pillar in a cross-section parallel to the substrate and including the third conductive layer is smaller than an area of the third pillar in a cross-section parallel to the substrate and including one of the first conductive layers,
the second semiconductor layer includes a third portion facing the uppermost one of the first conductive layers and a fourth portion facing the third conductive layer, and the second semiconductor layer is continuous at least from the third portion to the fourth portion,
between the first pillar and the third pillar, a pillar penetrating the first conductive layers is not provided, and
each of the second pillar and the fourth pillar is separated from the insulator.

16. The device of claim 15, wherein
the first conductive layers, the second conductive layer, the third conductive layer, and the insulator respectively extend in a second direction intersecting the first direction.

17. The device of claim 16, wherein
in a plan view, a center of the first pillar and a center of the second pillar are shifted in a third direction intersecting the first direction and the second direction, and a center of the third pillar and a center of the fourth pillar are shifted in the third direction.

18. The device of claim 17, wherein
in a plan view, the second pillar and the fourth pillar face each other via the insulator; the center of the second pillar is shifted, relative to the center of the first pillar, opposite a side thereof facing the fourth pillar in the third direction; and the center of the fourth pillar is shifted, relative to the center of the third pillar, opposite a side thereof facing the second pillar in the third direction.

19. The device of claim 1, further comprising:
a fourth conductive layer provided between the substrate and the first conductive layers,
wherein a side surface of the first semiconductor layer is in contact with the fourth conductive layer.

20. The device of claim 1, further comprising:
a fourth conductive layer provided between the substrate and the first conductive layers,
wherein a bottom surface of the first semiconductor layer is in contact with the fourth conductive layer.
